(19) United States
(12) Patent Application Publication
(10) Pub. No.: US 2010/0207689 A1
(43) Pub. Date: Aug. 19, 2010

(54) NOISE SUPPRESSION DEVICE, ITS METHOD, AND PROGRAM

(75) Inventor: Osamu Shimada, Tokyo (JP)

Correspondence Address: SCULLY SCOTT MURPHY & PRESSER, PC, 400 GARDEN CITY PLAZA, SUITE 300, GARDEN CITY, NY, 11530, US

(73) Assignee: NEC CORPORATION, Tokyo (JP)

(21) Appl. No.: 12/678,975

(22) PCT Filed: Sep. 18, 2008
(86) PCT No.: PCT/JP2008/066871

§ 371 Date: Mar. 18, 2010

(30) Foreign Application Priority Data
Sep. 19, 2007 (JP) JP 2007-243001

(51) Int. Cl. H03K 5/00

(52) U.S. Cl. 327/551

(57) ABSTRACT

A noise suppression device includes: conversion means which converts an input signal into a frequency region signal for each predetermined first frame; frame generation means which generates a second frame which is different from the first frame; representative frequency region signal generation means which generates a representative frequency region signal from the frequency region signal of the first frame contained in the second frame; and noise suppression degree calculation means which obtains a noise suppression degree of the second frame according to the representative frequency region signal.

### APPLICABLE FIELD IN THE INDUSTRY

The present invention relates to a noise suppression device for suppressing noise superposed upon a desired sound signal, and its method and program.

### BACKGROUND ART

As a device for suppressing background noise of an input signal that is configured of desired sound and background noise, a noise suppression device (hereinafter, referred to as a noise suppressor) is known. The noise suppressor is a device for suppressing noise superposed upon a desired sound signal. The noise suppressor operates, as a rule, so as to suppress the noise coexisting in the desired sound signal by employing an input signal converted in a frequency region, thereby to estimate a power spectrum of a noise component, and subtracting this estimated power spectrum from the input signal. In addition, successively estimating the power spectrum of the noise component enables the noise suppressor to be applied also for the suppression of non-constant noise. There exists, for example, the technique described in Patent document 1 as a noise suppressor.

A configuration of the noise suppressor disclosed in the Patent document 1 will be explained by making a reference to FIG. 35. A signal (hereinafter, referred to as a degraded sound signal) supplied to an input terminal 901 of FIG. 35 as a sample value sequence, in which the desired sound signal and the noise coexist, is divided into converted frames for each decided sample in a converted frame division unit 902. The degraded sound signal divided into the converted frames is subjected to the conversion such as a Fourier transform in a conversion unit 905, and is divided into a plurality of frequency components. And the conversion unit 905 supplies the power spectrum of the degraded sound signal obtained by employing an amplitude value of the signal divided into the frequency components to a noise suppression information calculation unit 907 and a noise suppression processing unit 908. The conversion unit 905 conveys a phase of the degraded sound signal to an inverse conversion unit 906. The noise suppression information calculation unit 907 calculates a suppression coefficient for each frequency by employing the degraded sound power spectrum, generates it as noise suppression information, and outputs it to the noise suppression processing unit 908. The suppression coefficient is a coefficient by which the degraded sound signal is multiplied for a purpose of obtaining a noise-suppressed emphasized sound. The noise suppression processing unit 908 multiplies the degraded sound power spectrum by the suppression coefficient of each frequency, being noise suppression information, obtains an emphasized sound power spectrum, and outputs it to the inverse conversion unit 906. The inverse conversion unit 906 matches the emphasized sound power spectrum supplied from the noise suppression processing unit 908 to the phase of the degraded sound signal supplied from the conversion unit 905, performs the inverse conversion for each converted frame, and outputs the emphasized sound signal divided into the converted frames to a converted frame composition unit 903. The converted frame composition unit 903 composes the emphasized sound signal divided into the converted frames, and outputs it as an emphasized sound signal sample to an output terminal 4. While an example employing the power spectrum in the process so far was explained, it is widely known that the amplitude value equivalent to a square root thereof can be employed instead of it.

Patent document 1: JP-P2002-204175A

### DISCLOSURE OF THE INVENTION

### Problems to be Solved by the Invention

However, in the conventional configuration explained by employing FIG. 35, the noise suppression information is calculated for each converted frame. That is, a processing frame length for calculating the noise suppression information, of which the length is identical to that of a converted frame length, is used in the conventional configuration. For this reason, when the converted frame length is lengthy, it is impossible to follow a change in the input signal when a change in the input signal occurs in a half way within the converted frame. The conventional configuration causes a problem that, at this time, the noise suppression information having a bad precision is calculated, and a sound quality of the output signal deteriorates. On the other hand, when the converted frame length is short, it is possible to follow a change in the input signal; however there exists a problem that the number of times at which the noise suppression information is calculated is increased and the arithmetic quantity is increased. An increase in the arithmetic quantity relating to the noise suppressor causes a problem that a noise suppression function cannot be incorporated when an important function other than the function of the noise compressor exists, or the other functions cannot be incorporated due to the incorporation of the noise suppression function. That is, the conventional method causes a problem that the high-quality noise suppression cannot be realized with a small arithmetic quantity.

Thereupon, the present invention has been accomplished in consideration of the above-mentioned problems, and an object thereof is to provide a noise suppression device that is capable of realizing the high-quality noise suppression with a small arithmetic quantity, and its method and program.

### Means to Solve the Problem

The present invention for solving the above-mentioned is a noise suppression device, comprising: a conversion means for converting an input signal into a frequency region signal for each decided first frame; a frame generation means for generating a second frame so that it differs from said first frame; a representative frequency region signal generation means for generating a representative frequency region signal from said frequency region signal of the first frame being included in said second frame; and a noise suppression degree calculation means for obtaining a degree of noise suppression of said second frame based upon said representative frequency region signal.

The present invention for solving the above-mentioned is a noise suppression method, comprising: a conversion step of converting an input signal into a frequency region signal for each decided first frame; a frame generation step of generating a second frame so that it differs from said first frame; a representative frequency region signal generation step of generating a representative frequency region signal from said frequency region signal of the first frame being included in said second frame; and a noise suppression degree calculation step of obtaining a degree of noise suppression of said second frame based upon said representative frequency region signal.

The present invention for solving the above-mentioned is a noise suppression program for causing a computer to execute: a conversion process of converting an input signal into a frequency region signal for each decided first frame; a frame generation process of generating a second frame so that it differs from said first frame; a representative frequency region signal generation process of generating a representative frequency region signal from said frequency region signal of the first frame being included in said second frame; and a noise suppression degree calculation process of obtaining a degree of noise suppression of said second frame based upon said representative frequency region signal.

### AN ADVANTAGEOUS EFFECT OF THE INVENTION

In the configuration of the present invention, the noise suppression information is calculated for each processing frame having two converted frames or more integrated therein. For this, the noise suppression having a high sound quality can be realized with a small arithmetic quantity owing to the configuration of the present invention.

### BRIEF DESCRIPTION OF THE DRAWINGS

FIG. 1 is a block diagram illustrating the best mode of the present invention.

FIG. 2 is a block diagram illustrating a configuration of a processing frame information generation unit being included in FIG. 1.

FIG. 3 is a view illustrating one example of a processing frame in a time group generation unit being included in FIG. 2.

FIG. 4 is a view illustrating one example of an integrated frequency band in a frequency group generation unit being included in FIG. 2.

FIG. 5 is a block diagram illustrating a second configuration of the processing frame information generation unit being included in FIG. 1.

FIG. 6 is a view illustrating one example of the integrated frequency band in the frequency group generation unit being included in FIG. 5.

FIG. 7 is a block diagram illustrating a configuration of a noise suppression information calculation unit being included in FIG. 1.

FIG. 8 is a block diagram illustrating a configuration of a noise estimation unit being included in FIG. 7.

FIG. 9 is a block diagram illustrating a configuration of an estimated noise calculation unit being included in FIG. 8.

FIG. 10 is a block diagram illustrating a configuration of an update determination unit being included in FIG. 9.

FIG. 11 is a block diagram illustrating a configuration of a weighted degraded sound calculation unit being included in FIG. 8.

FIG. 12 is a block diagram illustrating an example of a non-linear function in a non-linear processing unit being included in FIG. 11.

FIG. 13 is a block diagram illustrating a configuration of a noise suppression coefficient generation unit being included in FIG. 7.

FIG. 14 is a block diagram illustrating a configuration of an estimated inherent-SNR calculation unit being included in FIG. 13.

FIG. 15 is a block diagram illustrating a configuration of a noise suppression coefficient calculation unit being included in FIG. 13.

FIG. 16 is a block diagram illustrating a configuration of a suppression coefficient amendment unit being included in FIG. 7.

FIG. 17 is a block diagram illustrating a second configuration of the noise suppression information calculation unit being included in FIG. 1.

FIG. 18 is a block diagram illustrating a configuration of the suppression coefficient amendment unit being included in FIG. 17.

FIG. 19 is a block diagram illustrating a second embodiment of the present invention.

FIG. 20 is a block diagram illustrating a configuration of the noise suppression information calculation unit being included in FIG. 19.

FIG. 21 is a block diagram illustrating a configuration of the noise estimation unit being included in FIG. 20.

FIG. 22 is a block diagram illustrating a second configuration of the noise suppression information calculation unit being included in FIG. 19.

FIG. 23 is a block diagram illustrating a third embodiment of the present invention.

FIG. 24 is a block diagram illustrating a configuration of the processing frame information generation unit being included in FIG. 23.

FIG. 25 is a block diagram illustrating a second configuration of the processing frame information generation unit being included in FIG. 23.

FIG. 26 is a block diagram illustrating a fourth embodiment of the present invention.

FIG. 27 is a block diagram illustrating a configuration of the processing frame information generation unit being included in FIG. 26.

FIG. 28 is a block diagram illustrating a fifth embodiment of the present invention.

FIG. 29 is a block diagram illustrating a configuration of the processing frame information generation unit being included in FIG. 28.

FIG. 30 is a block diagram illustrating a sixth embodiment of the present invention.

FIG. 31 is a block diagram illustrating a configuration of the processing frame information generation unit being included in FIG. 30.

FIG. 32 is a block diagram illustrating a seventh embodiment of the present invention.

FIG. 33 is a block diagram illustrating an eighth embodiment of the present invention.

FIG. 34 is a block diagram illustrating a ninth embodiment of the present invention.

FIG. 35 is a block diagram illustrating the conventional configuration.

FIG. 36 is a flowchart indicating one example of a processing operation of the time group generation unit.

### DESCRIPTION OF NUMERALS

1, 901 input terminals
2, 902 converted frame division units
3, 903 converted frame composition units
4, 904 output terminals
5, 905 conversion units
6, 906 inverse conversion units
7, 12, 13, 14, 15 processing frame information generation units
8 representative frequency region signal generation unit
9, 11, 907 noise suppression information calculation units
10, 16, 908 noise suppression processing units
30 record unit
31 reproduction unit
32 multiplexing unit
33 separation unit
50, 57 converted frame energy calculation units
51, 55, 58, 59, 60 time group generation units
52, 54, 56 frequency group generation units
53 frequency energy calculation unit
300, 301 noise estimation unit
310 estimated noise calculation unit
320 weighted degraded sound calculation unit
330, 331, 480 counters
400 update determination unit
410 register length storage unit
420, 3201 estimated noise storage units
430, 1595 switches
440 shift register
450, 6208 adders
460 minimum value selection unit
470 division unit
601, 602 noise suppression coefficient generation units
610 acquired SNR calculation unit
620 estimated inherent-SNR calculation unit
630 noise suppression coefficient calculation unit
640 sound non-existence probability storage unit
660, 1597, 3203, 6204, 6205 multipliers
670 sound existence probability calculation unit
680 temporary output SNR calculation unit
1000 computer
1501, 1502 suppression coefficient amendment unit
1591, 6511 maximum value selection unit
1592 suppression coefficient lower-limit value storage unit
1593 threshold storage unit
1594, 4002, 4004 comparison units
1596 corrected value storage unit
3202 SNR calculation unit
3204 non-linear processing unit
4001 logic sum calculation unit
4003, 4005 threshold storage units
4006 threshold calculation unit
6201 value range restriction processing unit
6202 acquired SNR storage unit
6203 suppression coefficient storage unit
6206 weight storage unit
6207 weighted addition unit
6301 MMSE STSA gain function value calculation unit
6302 generalized likelihood ratio calculation unit
6303 suppression coefficient calculation unit
6512 suppression coefficient lower-limit value calculation unit

### BEST MODE FOR CARRYING OUT THE INVENTION

Embodiments of the noise suppression device of the present invention will be explained in details by making a reference to the accompanied drawings.

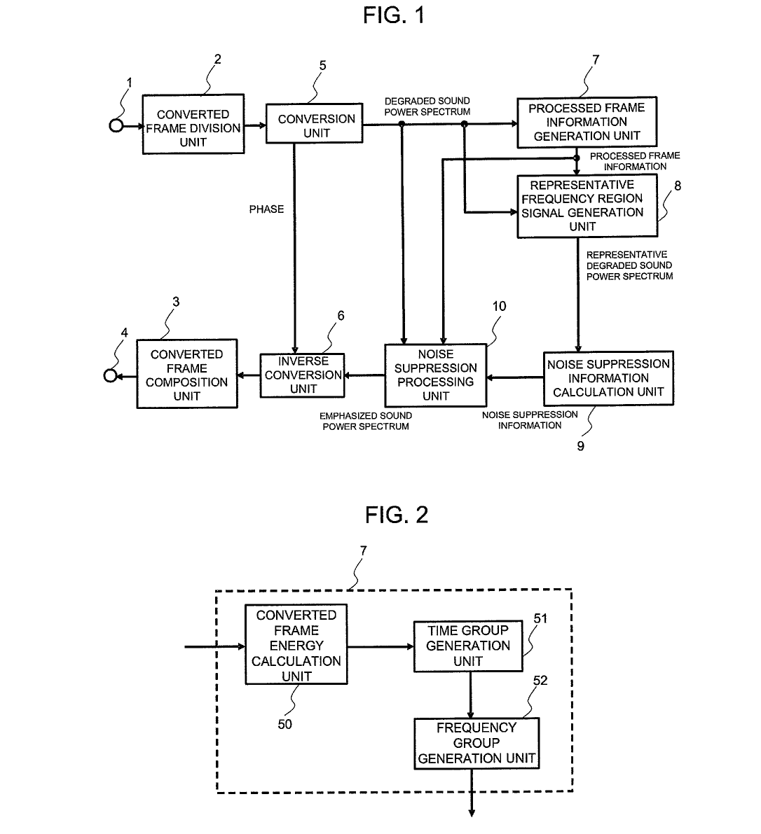

A configuration of the best mode of the present invention will be explained by making a reference to FIG. 1. The noise suppression device of the present invention is configured of an input terminal 1, a converted frame division unit 2, a converted frame composition unit 3, an output terminal 4, a conversion unit 5, an inverse conversion unit 6, a processing frame information generation unit 7, a representative frequency region signal generation unit 8, a noise suppression information calculation unit 9, and a noise suppression processing unit 10.

The input signal, being a degraded sound signal, is supplied as a sample value sequence to the input terminal 1. The input signal sample is supplied to the converted frame division unit 2, and divided into decided converted frame lengths. The converted frame division unit 2 outputs the input signal sample of an n-th converted frame to the conversion unit 5. The conversion unit 5 converts the input signal sample of the n-th converted frame into a degraded sound spectrum Yₙ(k), being a signal of the frequency region. Herein, n indicates an index in a time direction of the converted frame. It is assumed that k indicates an index in a frequency direction, and the input signal sample of the n-th converted frame is divided into K frequency bands (0≦k<K). The conversion unit 5 separates the degraded sound spectrum Yₙ(k) into a phase and an amplitude, outputs arg Yₙ(k), being a phase, to the inverse conversion unit 6, and outputs a degraded sound power spectrum |Yₙ(k)|² to the processing frame information generation unit 7, the representative frequency region signal generation unit 8, and the noise suppression processing unit 10.

The conversion unit 5 applies a frequency conversion for the input signal sample divided into the converted frames as a method of converting the input signal sample of the n-th converted frame into the degraded sound spectrum Yₙ(k). As an example of the frequency conversion, a Fourier transform, a cosine transform, a KL (Karhunen Loeve) transform, etc. are known. The technology related to a specific arithmetic operation of these transforms, and its properties are disclosed in Non-patent document 1 (DIGITAL CODING OF WAVEFORMS, PRINCIPLES AND APPLICATIONS TO SPEECH AND VIDEO, PRENTICE-HALL, 1990). Further, it is widely known that other conversions such as a Hadamard transform, a Haar transform, and a wavelet transform can be employed.

The conversion unit 5 also can apply the foregoing transforms for a result obtained by weighting the input signal sample of the above converted frame with a window function W. As such a window function, the window functions such as a Hamming window, a Hanning (Hann) window, a Kaiser window, and a Blackman window are known. Further, more complicated window functions can be employed. The technology related to these window functions is disclosed in Non-patent document 2 (DIGITAL SIGNAL PROCESSING, PRENTICE-HALL, 1975) and Non-patent document 3 (MULTIRATE SYSTEMS AND FILTER BANKS, PRENTICE-HALL, 1993). In addition, it is also widely conducted to partially superpose (overlap) the continuous two converted frames or more upon each other for windowing. In this case, the foregoing frequency conversion is applied for the signal windowed with superposition. The technology relating to the blocking involving the overlap and the conversion is disclosed in the Non-patent document 2.

In addition, the conversion unit 5 may be configured of a band-division filter bank to calculate the degraded sound spectrum Yₙ(k). The band-division filter bank is configured of a plurality of band-pass filters. An interval of each frequency band of the band-division filter bank could be equal in some cases, and unequal in some cases. Performing the unequal-interval band division makes it possible to lower/raise a time resolution, that is, the time resolution can be lowered by performing the division into narrow bands with regard to a low-frequency area, and the time resolution can be raised by performing the division into wide bands with regard to a high-frequency area. As a typified example of the unequal-interval division, there exists an octave division in which the band gradually halves toward the low-frequency area, a critical band division that corresponds to an auditory feature of a human being, or the like. After the conversion unit 5 performs the division into the equal-interval frequency bands, it may employ a hybrid filter bank for further band-dividing only the low-frequency area in order to enhance a frequency resolution of the frequency band in the low-frequency area. The technology relating to the band-division filter bank and its design method is disclosed in the Non-patent document 3.

The processing frame information generation unit 7 calculates processing frame information for generating a representative degraded sound power spectrum, which is later described, from the degraded sound power spectrum. Information for integrating a plurality of the degraded sound power spectra in the time direction and in the frequency direction is included in the processing frame information. The processing frame information generation unit 7 being included in FIG. 1 will be explained in details by making a reference to FIG. 2. The processing frame information generation unit 7 is configured of a converted frame energy calculation unit 50, a time group generation unit 51, and a frequency group generation unit 52.

The converted frame energy calculation unit 50 obtains a converted frame energy E(n) of the above converted frame from the degraded sound power spectrum |Yₙ(k)|², and outputs it to the time group generation unit 51. The converted frame energy E(n) becomes the following equation.

$$E ( n ) = {\sum }_{k = 0}^{K - 1} {\vert {Y}_{n} ( k ) \vert}^{2} \qquad [ Numerical equation 1 ]$$

Herein, a sum of the energies of the degraded sound power spectra of all frequency bands is defined as the converted frame energy. However, the converted frame energy may be calculated from the degraded sound power spectrum of only one part of the frequency bands. For example, the converted frame energy may be calculated from the degraded sound power spectrum of only the band in which a power of the sound signal concentrates. With this, the generation of the processing frame, which is later described, can be performed at a high standard of quality. Further, calculating the converted frame energy without using the signal of the low-frequency band enables an influence of the noise component, which is inclined to concentrate in the low-frequency area, to be removed.

In addition, the degraded sound power spectrum may be weighted in the frequency direction to employ a sum of the weighted values as the converted frame energy. Besides it, the calculated converted frame energy may be smoothed in the time direction.

Herein, the calculated converted frame energy can be also modified according to an auditory feature. For example, it is known that perception of an intensity of the sound is proportional to a logarithm thereof as an auditory feature of a human being. The value obtained by logarithmizing the energy can be defined as the converted frame energy by employing this feature. The converted frame energy also can be modified by employing not only the simple logarithm but also a more complicated function and polynomial expression. The polynomial expression approximating the logarithm, which is one example of these, contributes a reduction in the arithmetic quantity.

The time group generation unit 51 decides a delimiter position of the processing frame for generating a representative degraded sound power spectrum, which is later described, based upon the converted frame energy. The time group generation unit 51 outputs the processing frame generated based upon the decided processing frame delimiter position to the frequency group generation unit 52. There exists the method of deciding the delimiter position of the processing frame based upon a change in the converted frame energy as a method of deciding the delimiter position of the processing frame.

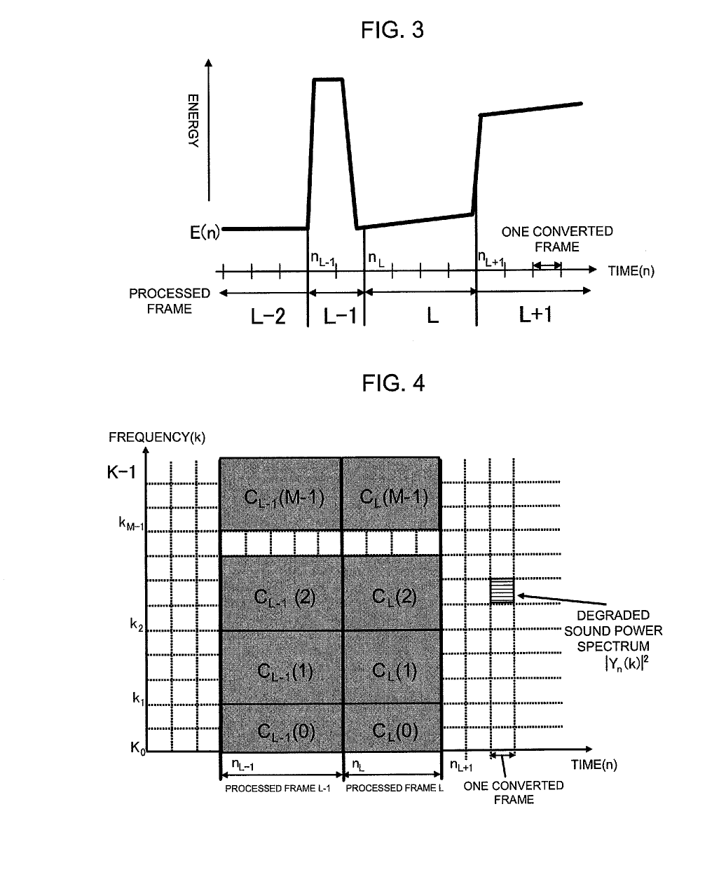

An example of a change in the converted frame energy will be explained by making a reference to FIG. 3. In FIG. 3, the converted frame energy is changed greatly at n=n_{L-1}, n_{L}, and n_{L+1}. When the delimiter position of the processing frame is decided so that the processing frame is divided at these locations, the delimiter position of an (L−1)-th processing frame becomes n=n_{L-1} and n=n_{L}, and the delimiter position of an L-th processing frame becomes n=n_{L} and n=n_{L+1}. As a result, the (L−1)-th processing frame is generated by integrating the converted frames ranging from an n_{L-1}-th converted frame to an (n_{L}−1)-th converted frame. The frame length of the (L−1)-th converted frame is n_{L}-n_{L-1}. On the other hand, the L-th processing frame is generated by integrating the converted frames ranging from an n_{L}-th converted frame to an (n_{L+1}−1)-th converted frame. The length of the above L-th processing frame becomes n_{L+1}-n_{L}.

As a method of detecting a location in which the converted frame energy is greatly changed, for example, there exists the method of determining that the converted frame energy has been greatly changed when the following equation is satisfied by employing a pre-determined threshold TH_{A}.

E(n_{L})−E(n_{L}−1)>TH_{A} [Numerical equation 2]

In the case of this method, the delimiter position of the processing frame is decided so that the processing frame is divided at n=n_{L}. At this time, the threshold TH_{A} can be also changed. For example, the threshold TH_{A} is adaptably changed based upon an average value or a dispersion value of the converted frame energies so that a ratio at which the Numerical equation 2 is satisfied is equalized in a certain constant block. Doing so makes it possible to reduce a dispersion of the numbers of times at which the arithmetic operation is performed for the noise suppression information that is later described.

As another method of generating the delimiter position of the processing frame, there exists the method of not calculating a change quantity only from the energies of the neighboring two converted frames, but calculating a change quantity by employing a plurality of the converted frame energies, and generating the delimiter position of the processing frame. For example, the delimiter position of the processing frame can be decided so that the processing frame is divided at n=n_{L} by employing the three converted frame energies when the following conditional equation is satisfied.

(E(n_{L})−E(n_{L}−1))·(E(n_{L})−E(n_{L}2))>TH_{B} [Numerical equation 3]

Where, TH_{B} is a threshold. At this time, the threshold TH_{B} can be also changed. For example, the threshold TH_{B} is adaptably changed based upon an average value or a dispersion value of the converted frame energies so that a ratio at which [Numerical equation 3] is satisfied is equalized in a certain constant block. Doing so makes it possible to reduce a dispersion of the numbers of times at which the arithmetic operations is performed for the noise suppression information that is later described.

As yet another method of deciding the delimiter position of the processing frame, there exists the method of deciding the delimiter position of the processing frame so that a minimum value and a maximum value of the converted frame energy being included in the above processing frame become equal to or less than a pre-decided threshold. In this case, the signal being included in the above processing frame resultantly has an equal energy or so, and the noise suppression information, which is later described, can be calculated at a high standard of quality. Further, the delimiter position of the processing frame may be generated so that a fixed processing frame length is yielded from the location in which the converted frame energy has been greatly changed. In this case, the arithmetic quantity can be reduced because the number of times at which a change in the energy is determined can be reduced.

In the foregoing, the method was explained of calculating the converted frame energy for each converted frame, and generating the delimiter position of the processing frame. So far as the above-mentioned method is concerned, it is also possible to calculate the converted frame energy in a unit obtained by integrating a plurality of the converted frames, and to generate the delimiter position of the processing frame based upon the calculated converted frame energy. In this case, the arithmetic quantity of the time group generation unit 51 can be reduced because the converted frame energy does not need to be calculated converted frame by converted frame. Further, it is also possible to analyze a change in the signal frequency band by frequency band, and to decide the delimiter position of the processing frame. As a result, an importance degree decided frequency band by frequency band can be reflected. For example, making an importance degree of the band in which the sound signal is included large enables a change in the signal of the above band to be easily reflected.

A feature of the degraded sound spectrum other than the converted frame energy may be employed as an index for deciding the delimiter position of the processing frame. For example, the delimiter position can be decided based upon the index such as a psychological auditory entropy. That is, this method is a method of actively employ a psychological auditory masking that the small sound in the adjacent of the large sound is hard to hear, being an auditory feature of a human being, or the like. It is a method of employing the psychological auditory masking, thereby to decide the delimiter position of the processing frame so that the processing frame is divided at the location in which a component of the sound that a human being can hear is changed. With this method, the processing frame based upon the auditory feature of a human being can be generated, and the noise suppression information, which is later described, can be calculated at a high standard of quality.

It is apparent that not only one of the above-mentioned methods is employed, but a combination thereof can be employed at the moment of deciding the delimiter position of the processing frame.

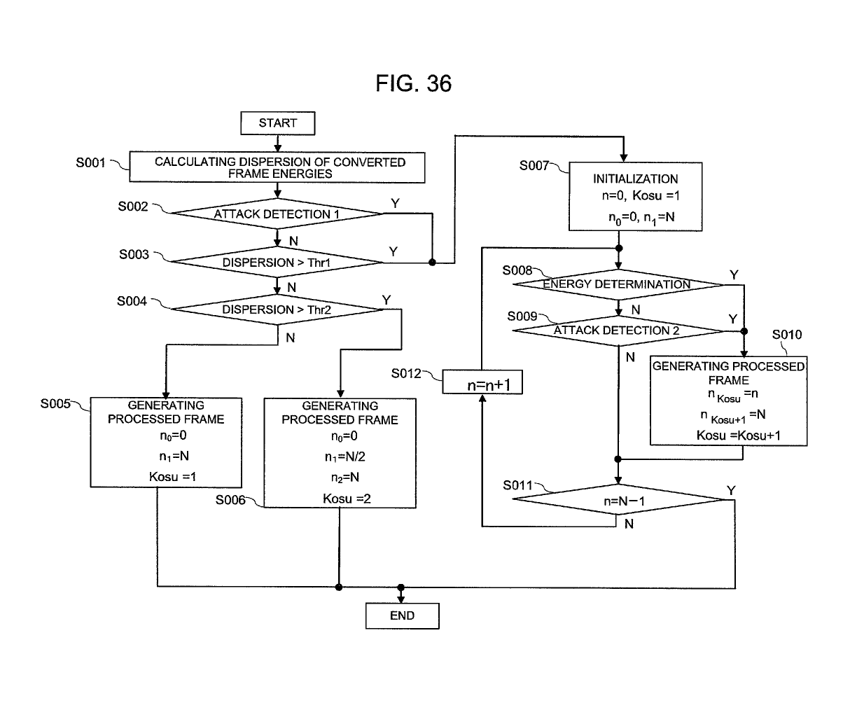

Herein, one example of a processing operation of the time group generation unit 51 will be explained by making a reference to a flowchart of FIG. 36.

The time group generation unit 51 calculates a dispersion of the converted frame energies with respect to N converted frames within a decided certain constant block (S001). Thereafter, the time group generation unit 51 determines whether N converted frames within the above constant block satisfy the foregoing Numerical equation 2 or Numerical equation 3 (S002). When the number of the converted frames satisfying the numerical equation is at least one, the process proceeds to S007. Contrarily, the number of the converted frames satisfying the foregoing Numerical equation 2 or Numerical equation 3 is zero, the process proceeds to S003.

In the S003, the time group generation unit 51 determines whether the calculated dispersion value is larger than a threshold Thr1, and advances the operation to the S007 when the dispersion value is larger than the threshold Thr1. On the other hand, when the dispersion value is smaller than the threshold Thr1, the process proceeds to S004. In the S004, the time group generation unit 51 determines whether the calculated dispersion value is larger than a threshold Thr2, and advances the operation to S005 when the dispersion value is smaller than the threshold Thr2.

In the S005, the above N converted frames are defined as one processing frame. Where each of n₀ and n₁ indicates the delimiter position of the processing frame, and Kosu indicates how many processing frames have been generated from the above N converted frames. On the other hand, when the dispersion value is larger than the threshold Thr2 in the S004, the process proceeds to S006. In the S006, the above N converted frames are defined as two processing frames. At this time, the delimiter position is set so that the processing frame lengths of the two processing frames become identical to each other. That is, n₁=N/2 is yielded

Continuously, an operation of the S007 and after it will be explained. In the S007, after the time group generation unit 51 initializes necessary variables, it investigates the above N converted frames in an order of n=0 to n=N−1, and determines whether the locations of these converted frames become a delimiter position of the processing frame, respectively. Next, in S008, the time group generation unit 51 determines whether an absolute value of a difference between the minimum value and the maximum value of the energy of the converted frame being included in the above processing frame is larger than a pre-decided threshold. When it is larger than the pre-decided threshold, the process proceeds to S010, and when it is smaller than the pre-decided threshold, the process proceeds to S009. Continuously, in the S009, the time group generation unit 51 determines whether the converted frame n satisfies the foregoing Numerical equation 2 or Numerical equation 3. In the S009, when the converted frame n satisfies the foregoing Numerical equation 2 or Numerical equation 3, the process proceeds to the S010. On the other hand, when the converted frame n does not satisfy the foregoing Numerical equation 2 or Numerical equation 3, the process proceeds to S011. In the S010, the time group generation unit 51 decides the delimiter position of the processing frame so that the processing frame is divided at the converted frame n, increase the number of the processing frames by one, and advances the process to the S011. In the S011, the time group generation unit 51 determines whether the investigation has been performed as far as the converted frame N−1, defines n as n=n+1 when the converted frame that should be investigated still remains (S012), and the process returns to the S008. When all of the above N converted frames have been investigated, the generation of the processing frame is finished.

Above, the explanation of one example of the processing operation of the time group generation unit 51 by making a reference to FIG. 36 is finished.

The frequency group generation unit 52 integrates the frequency bands for each processing frame supplied by the time group generation unit 51, and decides the delimiter position of the integrated frequency band for calculating the representative degraded sound power spectrum, which is later described. Thereafter, the frequency group generation unit 52 outputs the delimiter position of the processing frame and the delimiter position of the integrated frequency band as processing frame information to the representative frequency region signal generation unit 8.

A situation in which the frequency bands are integrated will be explained by making a reference to FIG. 4. Each grid circled by a short dashes line indicates one degraded sound power spectrum. The traverse axis indicates the time direction, and one measure of the traverse axis indicates one converted frame. The longitudinal axis indicates the frequency direction, and one measure of the longitudinal axis indicates one frequency band converted by the conversion unit 5. The foregoing process of the time group generation unit 51 is equivalent to the decision of the delimiter for integrating the measures in the time direction, being the traverse axis of FIG. 4. FIG. 4 indicates the (L−1)-th processing frame and the L-th processing frame generated by the time group generation unit 51. The (L−1)-th processing frame and the L-th processing frame are ones generated by delimiting the processing frame at n=n_{L-1}, n_{L}, and n_{L+1}. Further, the process in the frequency group generation unit 52 is equivalent to the integration of the measures in the frequency direction, being the longitudinal axis of FIG. 4. FIG. 4 indicates the case that K frequency bands are integrated into M frequency bands. The delimiter positions in the frequency direction of the L-th processing frame are defined as k_{L,P}(p=0, 1, . . . , M), k_{L,0}=0, and k_{L,M}=K. The processing frame information of the L-th processing frame is configured of the delimiter position (n=n_{L}, n_{L+1}) of the processing frame in the time direction, and the delimiter position (k=k_{L,0}, . . . , k_{L,M}) of the integrated frequency band in the frequency direction.

At this time, more numerous bands may be integrated into one in the high-frequency region as compared with the low-frequency region. That is, it means that more numerous frequency components are integrated into one in the higher-frequency region component, and an unequal-interval division is performed. As an example of such an unequal-interval division, an octave division in which the band is widened according to a power of 2 toward the high-frequency region side, a division according to critical bands band-divided based upon the auditory feature of a human being, and so on are known. In particular, the band division according to the critical band is widely employed because consistency with the auditory feature of a human being is high. Deterioration in the noise suppression feature is also prevented from occurring by integrating the frequency bands into a group smaller than the critical band at the time of integrating them.

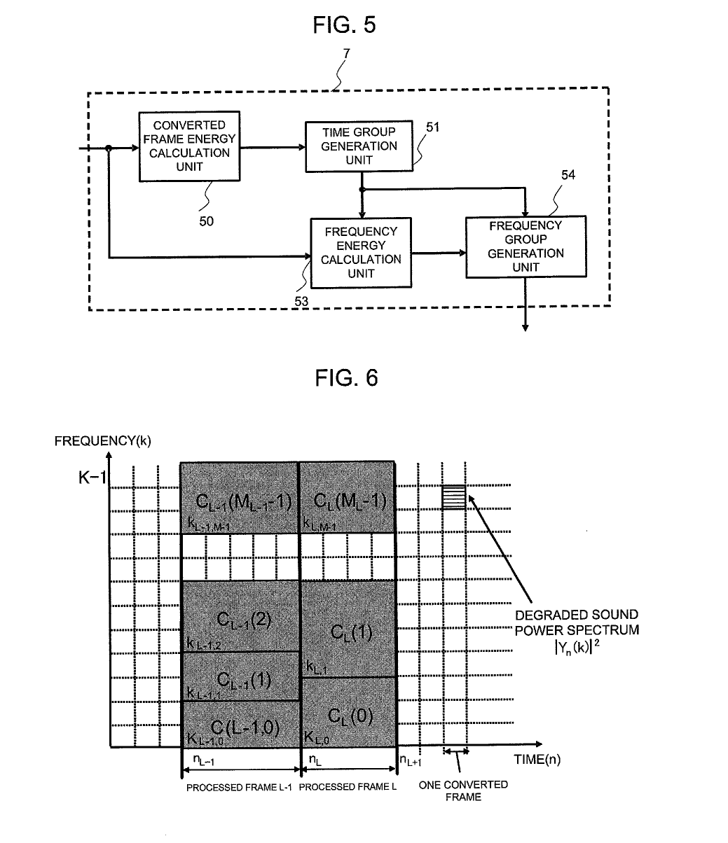

Next, a second configuration example of the processing frame information generation unit 7 will be explained in details by making a reference to FIG. 5. Upon making a comparison with the processing frame information generation unit 7 of FIG. 2, this processing frame information generation unit 7 is characterized in that it newly includes a frequency energy calculation unit 53, and the frequency group generation unit 52 is replaced with a frequency group generation unit 54. Hereinafter, the frequency energy calculation unit 53 and the frequency group generation unit 54, which are characteristic of the present invention, will be explained in details.

From the degraded sound power spectrum and the processing frame, the frequency energy calculation unit 53 obtains a frequency energy Ef_{L}(k), being a sum of the energies of the degraded sound power spectra of the identical frequency band in the above processing frame. The frequency energy calculation unit 53 outputs the frequency energy Ef_{L}(k) to the frequency group generation unit 54. That is, the frequency energy Ef_{L}(k) of the processing frame L becomes the following equation.

$${Ef}_{L} ( k ) = {\sum }_{n = {n}_{L}}^{{n}_{L} - 1} {\vert {Y}_{n} ( k ) \vert}^{2} \qquad [ Numerical equation 4 ]$$

The frequency group generation unit 54 integrates the frequency bands, which resemble each other in the feature of the degraded sound power spectrum, in a processing frame unit based upon the processing frame supplied from the time group generation unit 51 and the frequency energy Ef_{L}(k) supplied from the frequency energy calculation unit 53. With this, the frequency group generation unit 54 decides the delimiter position of the integrated frequency band.

A situation in which the frequency bands are integrated in each processing frame will be explained by making a reference to FIG. 6. The traverse axis and the longitudinal axis thereof are identical to that of FIG. 4. FIG. 6 shows the case that K frequency bands are integrated into M_{L-1} frequency bands in the (L−1)-th processing frame, and K frequency bands are integrated into M_{L} frequency bands in the L-th processing frame. The delimiter positions in the frequency direction of the processing frame L are defined as k_{L,P}(p=0, 1, . . . , M_{L}), k_{L,0}=0, and k_{L,ML}=K. The processing frame information is configured of the delimiter position of the processing frame, being the delimiter position in the time direction, and the delimiter position of the integrated frequency band, being the delimiter position in the frequency direction.

With regard to the integration of the frequency band, the delimiter position of the integrated frequency band is decided so that the integrated frequency band is divided at the location in which a change in the frequency energy is large. For example, the frequency bands may be integrated by applying the method based upon the energy change explained in the time group generation unit 51 for the frequency direction. Making such a configuration enables the best suitable integration of the frequency bands to be realized in each processing frame. For this, the integration into unnecessarily many frequency bands can be suppressed when a change in the signal is small, and the arithmetic quantity can be reduced.

Above, the explanation of the second configuration example of the processing frame information generation unit 7 is finished.

Constituting the processing frame information generation unit 7 as mentioned above makes it possible to generate the processing frame having a plurality of the converted frames integrated therein. At this time, the converted frames being included in the processing frame resembles each other in the feature of the degraded sound power spectrum, whereby respective items of the noise suppression information calculated for each of the above converted frames have an analogous value. The noise suppression information will be described later. For this reason, almost no difference occurs of the effect between the noise suppression by the noise suppression information calculated converted frame by converted frame, and the noise suppression by the noise suppression information calculated processing frame by processing frame. Owing to this, there is no possibility that the effect of the noise suppression declines even though the noise suppression information calculated processing frame by processing frame is employed. Thus, no possibility of exerting an influence upon the final noise suppression exists even though the arithmetic quantity is reduced by calculating the noise suppression information processing frame by processing frame.

Above, the explanation of the processing frame information generation unit 7 is finished.

The representative frequency region signal generation unit 8 generates a representative degraded sound power spectrum by employing the processing frame information and the degraded sound power spectrum. And the representative frequency region signal generation unit 8 outputs the representative degraded sound power spectrum to the noise suppression information calculation unit 9. As a method of generating the representative degraded sound power spectrum, there exists the method of employing an average value of the degraded sound power spectra that are included in the above processing frame and in the above integrated frequency band. In this case, a representative degraded sound power spectrum |Z_{L}(m)|² (m=0, . . . , M_{L}−1) of the L-th processing frame becomes the following equation.

$${\vert {Z}_{L} ( m ) \vert}^{2} = \frac{{\sum }_{k = {k}_{L , m}}^{{k}_{L , m + 1} - 1} {\sum }_{n = {n}_{L}}^{{n}_{L + 1} - 1} {\vert {Y}_{n} ( k ) \vert}^{2}}{( {k}_{L , m + 1} - {k}_{L , m} ) \cdot ( {n}_{L + 1} - {n}_{L} )} \qquad [ Numerical equation 5 ]$$

That is, in FIG. 4 and FIG. 6, this is equivalent to the calculation of one value per one grid encircled by gray.

Further, there exists the method of obtaining an average value of the degraded sound power spectra except the large degraded sound power spectrum and the small degraded sound power spectrum besides the method of employing an average value of all of the degraded sound power spectra. Doing so makes it possible to remove the unexpected degraded sound power spectrum, whereby the representative degraded sound power spectrum is stabilized, and a degree of the noise suppression, which is later described, can be calculated at a high standard of quality.

Besides, the method as well exists of not employing an average value, but employing a specific degraded sound power spectrum as the representative degraded sound power spectrum. For example, when the maximum value of the degraded sound power spectrum, which is included in the above processing frame and in the above integrated frequency region, is defined as the representative degraded sound power spectrum, the noise component is resultantly estimated to be in a high level at the moment of calculating the noise suppression information that is described later. In this case, residual noise being included in the noise-suppressed emphasized sound can be made small. On the other hand, when the minimum value of the degraded sound power spectrum, which is included in the above processing frame and in the above integrated frequency region, is defined as the representative degraded sound power spectrum, the noise component is resultantly estimated to be in a low level at the moment of calculating the noise suppression information that is described later. In this case, strain of the noise-suppressed emphasized sound can be made small.

The noise suppression information calculation unit 9 obtains the noise suppression information indicative of a degree of one noise suppression for each representative degraded sound power spectrum. And, the noise suppression information calculation unit 9 outputs the noise suppression information to the noise suppression processing unit 10. That is, the noise suppression information calculation unit 9 calculates the noise suppression information common to a plurality of the degraded sound power spectra. This is equivalent to the calculation of one item of noise suppression information C_{L}(m)(m=0 . . . , M_{L}−1) per one grid encircled by gray in FIG. 4 and FIG. 6.

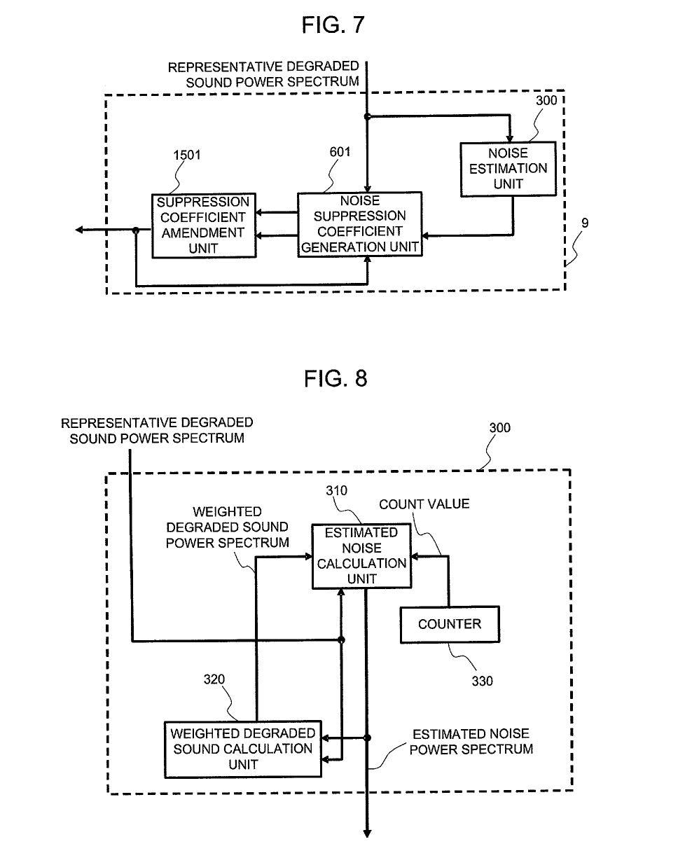

A first configuration example of the noise suppression information calculation unit 9 will be explained in details by making a reference to FIG. 7. The noise suppression information calculation unit 9 is configured of a noise estimation unit 300, a noise suppression coefficient generation unit 601, and a suppression coefficient amendment unit 1501.

The noise estimation unit 300 estimates the energy of the noise component being included in the degraded sound based upon the representative degraded sound power spectrum. The noise estimation unit 300 outputs the energy of the estimated noise component as an estimated noise power spectrum to the noise suppression coefficient generation unit 601. The noise suppression coefficient generation unit 601 obtains a suppression coefficient based upon the representative degraded sound power spectrum, the estimated noise power spectrum, and an amended suppression coefficient, which is described later, and estimates an inherent SNR indicative of a ratio between the sound and the noise being included in the input signal. The estimated inherent SNR will be described later. The noise suppression coefficient generation unit 601 outputs the suppression coefficient and the estimated inherent SNR to the suppression coefficient amendment unit 1501. The suppression coefficient amendment unit 1501 amends the inputted suppression coefficient based upon the estimated inherent SNR, and obtains the amended suppression coefficient. The suppression coefficient amendment unit 1501 outputs the amended suppression coefficient as noise suppression information, and simultaneously therewith, outputs it to the noise suppression coefficient generation unit 601.

A configuration example of the noise estimation unit 300 being included in FIG. 7 will be explained by making a reference to FIG. 8. The noise estimation unit 300 is configured of an estimated noise calculation unit 310, a weighted degraded sound calculation unit 320 and a counter 330. The representative degraded sound power spectrum inputted into the noise estimation unit 300 is inputted into the estimated noise calculation unit 310 and the weighted degraded sound calculation unit 320. The weighted degraded sound calculation unit 320 calculates a weighted degraded sound power spectrum by employing the inputted representative degraded sound power spectrum and the estimated noise power spectrum. The weighted degraded sound calculation unit 320 outputs the weighted degraded sound power spectrum to the estimated noise calculation unit 310. The estimated noise calculation unit 310 estimates the power spectrum of the noise by employing the representative degraded sound power spectrum, the weighted degraded sound power spectrum, and a count value being inputted from the counter 330. The estimated noise calculation unit 310 outputs the estimated noise power spectrum as an output of the noise estimation unit 300. In addition, the estimated noise calculation unit 310 outputs the estimated noise power spectrum to the weighted degraded sound calculation unit 320. The counter 330 outputs the count value. An initial value of the count value is set to 0. The counter 330 increases the count value by 1 processing frame by processing frame.

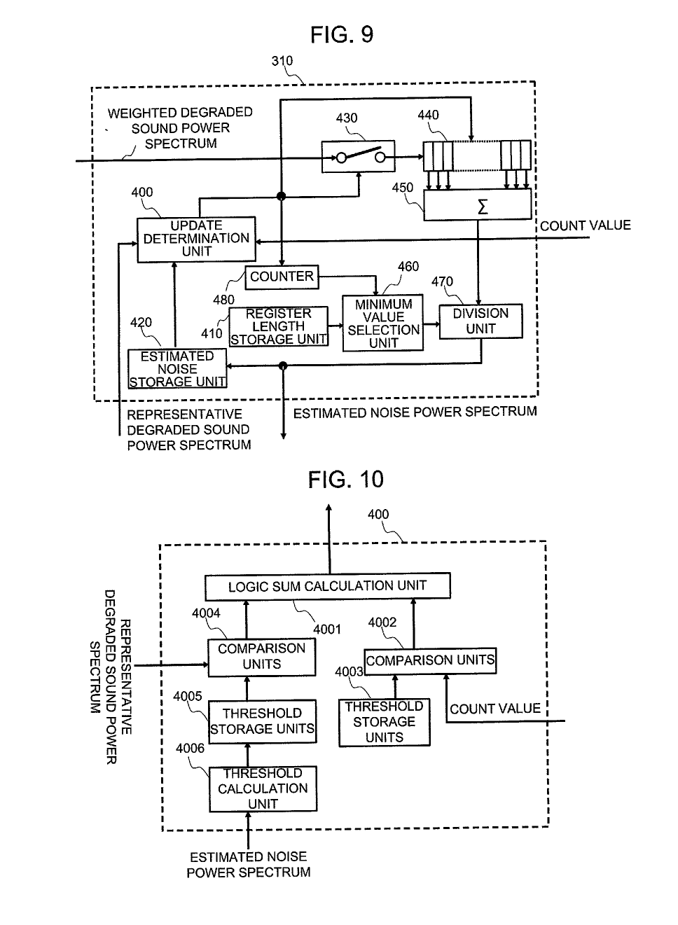

A configuration of the estimated noise calculation unit 310 being included in FIG. 8 will be explained in details by making a reference to FIG. 9. The estimated noise calculation unit 310 is configured of an update determination unit 400, a register length storage unit 410, an estimated noise storage unit 420, a switch 430, a shift register 440, an adder 450, a minimum value selection unit 460, a division unit 470, and a counter 480. The weighted degraded sound power spectrum is inputted into the switch 430. When the switch 430 closes a circuit, the weighted degraded sound power spectrum is inputted into the shift register 440. The shift register 440, responding to a control signal being inputted from the update determination unit 400 shifts a storage value of the internal register to the neighboring register. A shift register length is equal to a value stored in the register length storage unit 410 to be later described. All of register outputs of the shift register 440 are outputted to the adder 450. The adder 450 adds all of the inputted register outputs. The adder 450 outputs an addition result to the division unit 470.

On the other hand, the count value, the representative degraded sound power spectrum, and the estimated noise power spectrum are inputted into the update determination unit 400. The update determination unit 400 outputs a signal of 1 or 0 to the counter 480, the switch 430, and the shift register 440. The update determination unit 400 outputs 1 at any time until the count value being inputted reaches a pre-set value. Further, the update determination unit 400 outputs 1 when it has been determined that the inputted degraded sound signal is noise after the count value reaches the pre-set value, and outputs 0 in the cases other than it. The switch 430 closes the circuit when the signal inputted from the update determination unit 400 is 1, and opens the circuit when it is 0. The counter 480 increase the count value when the signal inputted from the update determination unit 400 is 1, and does not change the count value when it is 0. The shift register 440 incorporates the signal sample being inputted from the switch 430 by one (1) sample when the signal inputted from the update determination unit 400 is 1. In addition, the shift register 440 shifts the storage value of the internal register to the neighboring register simultaneously therewith the incorporation of one (1) sample. The output of the counter 480 and the output of the register length storage unit 410 are inputted into the minimum value selection unit 460.

The minimum value selection unit 460 selects one of the inputted count value and register length, which is smaller, and outputs it to the division unit 470. The division unit 470 divides the addition value of the representative degraded sound power spectrum inputted from the adder 450 by one of the count value and the register length, which is smaller. The division unit 470 outputs a quotient obtained by the division as an estimated noise power spectrum λ_{L}(m). Upon defining B₁(m) (1=0, 1, . . . , P−1) as a sample value of the weighted degraded sound power spectrum saved in the shift register 440, λ_{L}(m) is given by the following equation.

$${λ}_{L} ( m ) = \frac{1}{P} {\sum }_{l = 0}^{P - 1} {B}_{l} ( m ) \qquad [ Numerical equation 6 ]$$

Where, P is one of the count value and the register length, which is smaller. The addition value is divided firstly by the count value because the count value is increased monotonously, to begin with zero. After the count value becomes larger than the register length, the addition value is divided by the register length. Dividing the addition value by the register length means that the average value of the values stored in the shift register is obtained. At first, a sufficiently many values have not been stored in the shift register 440, whereby the division is executed by using the number of the registers into which the value has been actually stored. The number of the registers in which the value has been actually stored is equal to the count value when the count value is smaller than the register length, and becomes equal to the register length when the former becomes larger than the latter.

A configuration of the update determination unit 400 being included in FIG. 9 will be explained in details by making a reference to FIG. 10. The update determination unit 400 is configured of a logic sum calculation unit 4001, comparison units 4004 and 4002, threshold storage units 4005 and 4003, and a threshold calculation unit 4006. The count value being inputted from the counter 330 of FIG. 8 is inputted into the comparison unit 4002. The threshold, being an output of the threshold storage unit 4003, is inputted into the comparison unit 4002. The comparison unit 4002 compares the inputted count value with the threshold, and outputs 1 to the logic sum calculation unit 4001 when the former is smaller than the latter, and 0 when the former is larger than the latter. On the other hand, the threshold calculation unit 4006 calculates the value that corresponds to the estimated noise power spectrum being supplied from the estimated noise storage unit 420 of FIG. 9, and outputs it as a threshold to the threshold storage unit 4005. As a simplest method of calculating the threshold, there exists the method of defining a constant multiplication of the estimated noise power spectrum as a threshold. Besides it, there also exists the method of calculating the threshold by employing a high-order polynomial expression or a non-linear function. The threshold storage unit 4005 stores the threshold outputted from the threshold calculation unit 4006. And, the threshold storage unit 4005 outputs the threshold stored one processing frame before to the comparison unit 4004. The comparison unit 4004 compares the threshold being inputted from the threshold storage unit 4005 with the representative degraded sound power spectrum being inputted from the representative frequency region signal generation unit 8 of FIG. 1. At this time, the comparison unit 4004 outputs 1 when the latter is smaller than the former, and 0 when the latter is larger to the logic sum calculation unit 4001. That is, it is determined whether or not the degraded sound signal is noise based upon magnitude of the estimated noise power spectrum. The logic sum, calculation unit 4001 calculates a logic sum of the output value of the comparison unit 4002 and the output value of the comparison unit 4004. And, the logic sum calculation unit 4001 outputs a calculation result to the switch 430, the shift register 440, and the counter 480 of FIG. 9. In such a manner, when the degraded sound power is smaller not only in an initial state and in a soundless section but also in a sounded section, the update determination unit 400 outputs 1. That is, the estimated noise is updated when the degraded sound power is smaller in a sounded section as well. The estimated noise can be updated for each frequency because the calculation of the threshold is executed for each frequency.

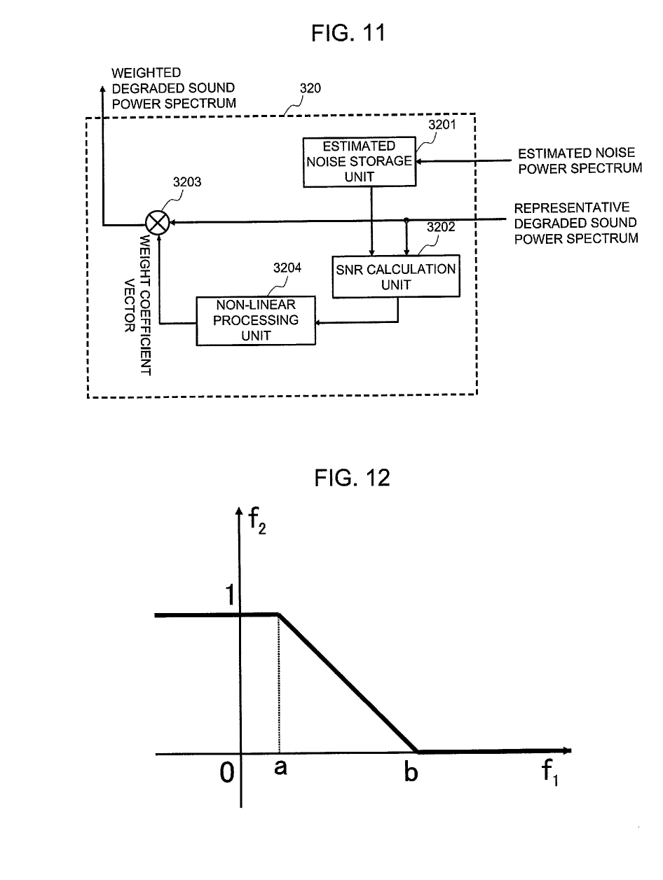

A configuration of the weighted degraded sound calculation unit 320 being included in the noise estimation unit 300 will be explained in details by making a reference to FIG. 11. The weighted degraded sound calculation unit 320 is configured of an estimated noise storage unit 3201, a SNR calculation unit 3202, a non-linear processing unit 3204, and a multiplier 3203. The estimated noise storage unit 3201 stores the estimated noise power spectrum being inputted from the estimated noise calculation unit 310 of FIG. 8. In addition, the estimated noise storage unit 3201 outputs the estimated noise power spectrum stored one processing frame before to the SNR calculation unit 3202. The SNR calculation unit 3202 obtains the SNR for each integrated frequency band by employing the estimated noise power spectrum being inputted from the estimated noise storage unit 3201 and the representative degraded sound power spectrum being inputted from the representative frequency region signal generation unit 8 of FIG. 1, and outputs it to the non-linear processing unit 3204. Specifically, the SNR calculation unit 3202, according to the following equation, divides the representative degraded sound power spectrum supplied from the representative frequency region signal generation unit 8 by the estimated noise power spectrum, thereby to obtain a SNR γhd L(m)-hat of the L-th processing frame.

$${\hat{γ}}_{L} ( m ) = \frac{{\vert {Z}_{L} ( m ) \vert}^{2}}{{λ}_{L - 1} ( m )} \qquad [ Numerical equation 7 ]$$

Where, λ_{L-1}(m) is the estimated noise power spectrum stored one processing frame before.

The non-linear processing unit 3204 calculates a weight coefficient vector by employing the SNR being inputted from the SNR calculation unit 3202. And, the non-linear processing unit 3204 outputs the weight coefficient vector to the multiplier 3203. The multiplier 3203 calculates a product of the representative degraded sound power spectrum being inputted from the representative frequency region signal generation unit 8 of FIG. 1 and the weight coefficient vector being inputted from the non-linear processing unit 3204 frequency band by frequency band. And, the multiplier 3203 outputs the weighted degraded sound power spectrum to the estimated noise calculation unit 310 of FIG. 8.

The non-linear processing unit 3204 has a non-linear function capable of outputting an actual value that corresponds to each of multiplexed input values. An example of the non-linear function is shown in FIG. 12. An output value f₂ of the non-linear function shown in FIG. 12 at the time of defining f₁ as an input value is given by the following equation.

$${f}_{2} = \{ \begin{matrix}1 , & {f}_{1} \leq a \\ \frac{{f}_{1} - b}{a - b} , & a < {f}_{1} \leq b \\ 0 , & b < {f}_{1}\end{matrix} \qquad [ Numerical equation 8 ]$$

Where, a and b are an optional actual number, respectively.

The non-linear processing unit 3204 processes the SNR being inputted from the SNR calculation unit 3202 with the non-linear function, thereby to obtain the weight coefficient, and outputs it to the multiplier 3203. That is, the non-linear processing unit 3204 outputs the weight coefficient of 1 up to 0 that corresponds to the SNR. It outputs 1 when the SNR is small, and 0 when the SNR is large.

The multiplier 3203 of FIG. 11 multiples the representative degraded sound power spectrum by the weight coefficient. The weight coefficient is a value that corresponds to the SNR. That is, the larger the SNR is, namely, the larger the sound component being included in the degraded sound is, the smaller the value of the weight coefficient becomes. As a rule, the representative degraded sound power spectrum is employed for updating the estimated noise. However, in the present invention, the weighting, which corresponds to the SNR, is conducted for the representative degraded sound power spectrum that is employed for updating the estimated noise. With this, an influence of the sound component being included in the representative degraded sound power spectrum can be made small, and a higher-precision noise estimation can be performed. Additionally, while an example employing the non-linear function for calculating the weight coefficient was shown, it is also possible to employ the function of the SNR that is expressed in other formats, for example, a linear function and a high-order polynomial expression besides the non-linear function.

Above, the explanation of the noise estimation unit 300 is finished.

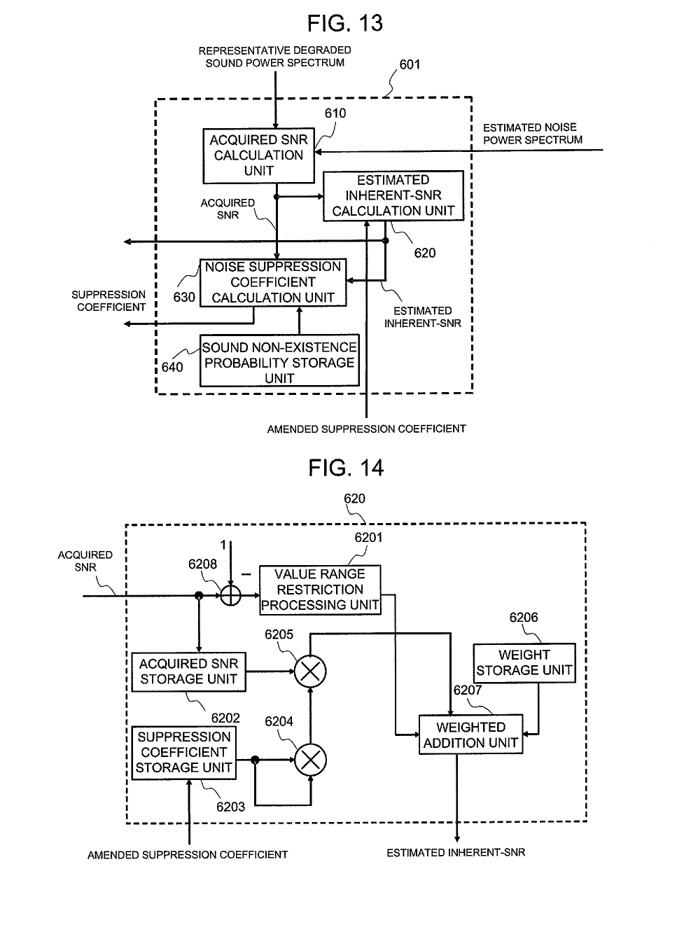

Continuously, a configuration of the noise suppression coefficient generation unit 601 of FIG. 7 will be explained in details by making a reference to FIG. 13.

The noise suppression coefficient generation unit 601 is configured of an acquired SNR calculation unit 610, an estimated inherent-SNR calculation unit 620, a noise suppression coefficient calculation unit 630, and a sound non-existence probability storage unit 640. The acquired SNR calculation unit 610 calculates the SNR for each integrated frequency band by employing the inputted representative degraded sound power spectrum and estimated noise power spectrum. And, the acquired SNR calculation unit 610 outputs a calculation result as an acquired SNR to the estimated inherent-SNR calculation unit 620 and the noise suppression coefficient calculation unit 630. The estimated inherent-SNR calculation unit 620 estimates the inherent SNR by employing the inputted acquired SNR, and the amended suppression coefficient inputted from the suppression coefficient amendment unit 1501. The estimated inherent-SNR calculation unit 620 outputs the estimated inherent SNR to the suppression coefficient amendment unit 1501. In addition, the estimated inherent-SNR calculation unit 620 outputs the estimated inherent SNR to the noise suppression coefficient calculation unit 630.

The noise suppression coefficient calculation unit 630 generates the suppression coefficient by employing the inputted acquired SNR and estimated inherent SNR, and a sound non-existence probability being inputted from the sound non-existence probability storage unit 640. The sound non-existence probability signifies a pre-decided probability that no sound is included in the input signal. And, the noise suppression coefficient calculation unit 630 outputs the suppression coefficient.

A configuration of the estimated inherent-SNR calculation unit 620 being included in FIG. 13 will be explained in details by making a reference to FIG. 14. The estimated inherent-SNR calculation unit 620 is configured of a value range restriction processing unit 6201, an acquired SNR storage unit 6202, a suppression coefficient storage unit 6203, multipliers 6204 and 6205, a weight storage unit 6206, a weighted addition unit 6207, and an adder 6208.

An acquired SNR γ_{L}(m) (m=0, 1, . . . , M_{L}−1) being inputted from the acquired SNR calculation unit 610 of FIG. 13 is inputted into the acquired SNR storage unit 6202 and the adder 6208. The acquired SNR storage unit 6202 stores the acquired SNR γ_{L}(m) of the L-th processing frame. Simultaneously therewith, the acquired SNR storage unit 6202 outputs an acquired SNR γ_{L-1}(m) of the (L−1)-th processing frame, being a one-before processing frame, to the multiplier 6205. An amended suppression coefficient C_{L}(m)(m=0, 1, . . . , M_{L}−1) of the L-th processing frame being inputted from the suppression coefficient amendment unit 1501 of FIG. 7 is inputted into the suppression coefficient storage unit 6203. The suppression coefficient storage unit 6203 stores the amended suppression coefficient C_{L}(m) of the L-th processing frame. Simultaneously therewith, the suppression coefficient storage unit 6203 outputs an amended suppression coefficient C_{L-1}(m)-bar of the (L−1)-th processing frame, being a one-before processing frame, to the multiplier 6204. The multiplier 6204 obtains C²_{L-1}(m) by squaring the supplied C_{L}(m), and outputs it to the multiplier 6205. The multiplier 6205 obtains C²_{L-1}(m) γ_{L-1}(m) by multiplying C²_{L-1}(m) by γ_{L-1}(m) with respect to m=0, 1, . . . , M_{L}−1. And, the multiplier 6205 outputs a calculation result as a past estimated SNR to the weighted addition unit 6207.

−1 is supplied to another terminal of the adder 6208, and an addition result γ_{L}(m)−1 is output to the value range restriction processing unit 6201. The value range restriction processing unit 6201 subjects the addition result γ_{L}(m)−1 inputted from the adder 6208 to an operation by a value range restriction operator P[•]. And, the value range restriction processing unit 6201 conveys P[γ_{L}(m)−1], being a result of the arithmetic operation, as a momentarily-estimated SNR to the weighted addition unit 6207. Where, P[x] is decided by the following equation.

$$P [ x ] = \{ \begin{matrix}x , & x > 0 \\ 0 , & x \leq 0\end{matrix} \qquad [ Numerical equation 9 ]$$

A weight is inputted into the weighted addition unit 6207 from the weight storage unit 6206. The weighted addition unit 6207 obtains the estimated inherent SNR by employing these inputted momentarily-estimated SNR, past estimated SNR, and weight. Upon defining the weight as α, and ξₙ(m)-hat as an estimated inherent SNR, the ξ_{L}(m)-hat is calculated by the following equation.

\hat{ξ}_{L}(m)=αγ_{L-1}(m)C_{L-1}²(m)+(1−α)P[γ_{L}(m)−1] [Numerical equation 10]

Where, it is assumed that γ₋₁(m)C²₋₁(m)=1.

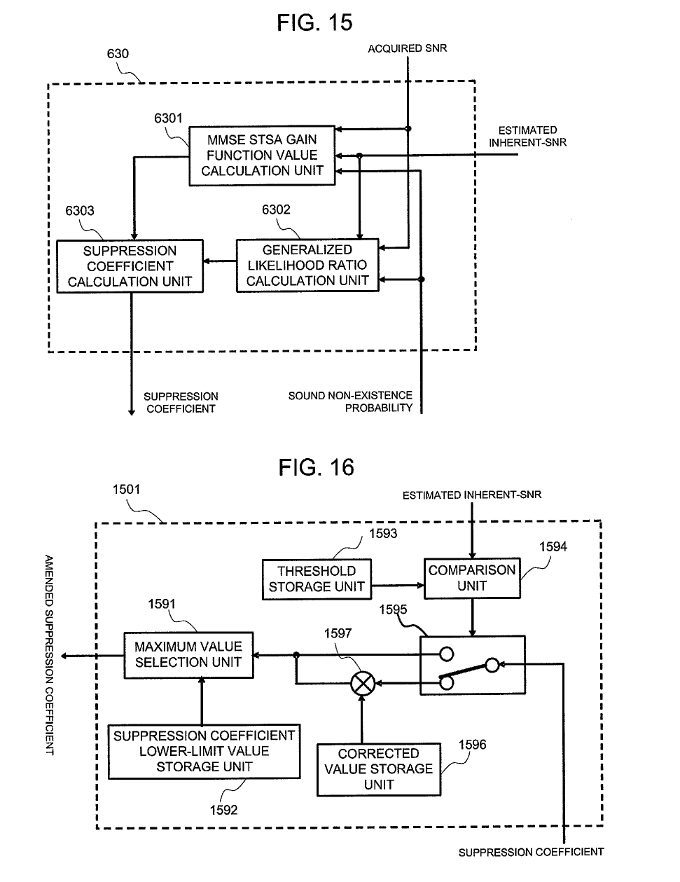

A configuration of the noise suppression coefficient calculation unit 630 being included in FIG. 13 will be explained in details by making a reference to FIG. 15. The noise suppression coefficient calculation unit 630 is configured of an MMSE STSA gain function value calculation unit 6301, a generalized likelihood ratio calculation unit 6302, and a suppression coefficient calculation unit 6303. Hereinafter, how to calculate the suppression coefficient will be explained based upon the calculation equation described in Non-patent document 4 (IEEE TRANSACTIONS ON ACOUSTICS, SPEECH, AND SIGNAL PROCESSING, Vol. 32, No. 6, pp. 1109 to 1121, December, 1984).

It is assumed that the processing frame number is L, the frequency number is m, γ_{L}(m) is a by-frequency acquired SNR being inputted from the acquired SNR calculation unit 610 of FIG. 13, ξ_{L}(m)-hat is an estimated inherent SNR being inputted from the estimated inherent-SNR calculation unit 620 of FIG. 13, and q is a sound non-existence probability being inputted from the sound non-existence probability storage unit 640 of FIG. 13. Further, it is assumed that η_{L}(m)=ξ_{L}(m)-hat/(1−q), and V_{L}(m)=(η_{L}(m)γ_{L}(m))/(1+η_{L}(m)).

The MMSE STSA gain function value calculation unit 6301 calculates an MMSE STSA gain function value frequency band by frequency band based upon the acquired SNR γ_{L}(m) being inputted from the acquired SNR calculation unit 610 of FIG. 13, the estimated inherent SNR ξ_{L}(m)-hat being inputted from the estimated inherent-SNR calculation unit 620 of FIG. 13, and the sound non-existence probability q being inputted from the sound non-existence probability storage unit 640 of FIG. 13, and outputs it to the suppression coefficient calculation unit 6303. An MMSE STSA gain function value G_{L}(m) by the integrated frequency band of the L-th processing frame is given by the following equation.

$$[ Numerical equation 11 ]$$

$${G}_{L} ( m ) = \frac{\sqrt{π}}{2} \frac{\sqrt{{v}_{L} ( m )}}{{γ}_{L} ( m )} exp ( - \frac{{v}_{L} ( m )}{2} ) [ ( 1 + {v}_{L} ( m ) ) {I}_{0} ( \frac{{v}_{L} ( m )}{2} ) + {v}_{L} ( m ) {I}_{1} ( \frac{{v}_{L} ( m )}{2} ) ]$$

Where, I₀(z) is a zero-order modified Bessel function, and I₁(z) is a first-order modified Bessel function.

The generalized likelihood ratio calculation unit 6302 calculates a generalized likelihood ratio frequency band by frequency band based upon the acquired SNR γ_{L}(m) being inputted from the acquired SNR calculation unit 610 of FIG. 13, the estimated inherent SNR ξ_{L}(m)-hat being inputted from the estimated inherent-SNR calculation unit 620 of FIG. 13, and the sound non-existence probability q being inputted from the sound non-existence probability storage unit 640 of FIG. 13. And, the generalized likelihood ratio calculation unit 6302 outputs the generalized likelihood ratio to the suppression coefficient calculation unit 6303. A generalized likelihood ratio Λ_{L}(m) by the frequency band of the L-th processing frame is given by the following equation.

$${Λ}_{L} ( m ) = \frac{1 - q}{q} \frac{exp ( {v}_{L} ( m ) )}{1 + {η}_{L} ( m )} \qquad [ Numerical equation 12 ]$$

The suppression coefficient calculation unit 6303 calculates the suppression coefficient frequency band by frequency band from the MMSE STSA gain function value G_{L}(m)-bar being inputted from the MMSE STSA gain function value calculation unit 6301, and the generalized likelihood ratio Λ_{L}(m) being inputted from the generalized likelihood ratio calculation unit 6302. And, the suppression coefficient calculation unit 6303 outputs the suppression coefficient to the suppression coefficient amendment unit 1501 of FIG. 7. A suppression coefficient C_{L}(m)-bar by the frequency band of the L-th processing frame is given by the following equation.

$${\overline{C}}_{L} ( m ) = \frac{{Λ}_{L} ( m )}{{Λ}_{L} ( m ) + 1} {G}_{L} ( m ) \qquad [ Numerical equation 13 ]$$

It is also possible to obtain the SNR common to a wide band that is configured of a plurality of the frequency bands and to employ the obtained common SNR instead of calculating the SNR frequency band by frequency band.

A configuration of the suppression coefficient amendment unit 1501 will be explained in details by making a reference to FIG. 16. The suppression coefficient amendment unit 1501 is configured of a maximum value selection unit 1591, a suppression coefficient lower-limit value storage unit 1592, a threshold storage unit 1593, a comparison unit 1594, a switch 1595, a corrected value storage unit 1596, and a multiplier 1597. The comparison unit 1594 compares the threshold being inputted from threshold storage unit 1593 with the estimated inherent SNR being inputted from the estimated inherent-SNR calculation unit 620 of FIG. 13 as an input coming from the noise suppression coefficient generation unit 601. And, the comparison unit 1594 inputs 0 into the switch 1595 when the latter is larger than the former, and 1 when the latter is smaller. The switch 1595 outputs the suppression coefficient being inputted from the noise suppression coefficient calculation unit 630 of FIG. 13 to the multiplier 1597 when the output value of the comparison unit 1594 is 1, and to the maximum value selection unit 1591 when it is 0. That is, the suppression coefficient is amended when the estimated inherent SNR is smaller than the threshold. The multiplier 1597 calculates a product of the output value of the switch 1595 and the output value of the corrected value storage unit 1596, and outputs it to the maximum value selection unit 1591.

On the other hand, the suppression coefficient lower-limit value storage unit 1592 outputs the lower limit value of the suppression coefficient stored by the suppression coefficient lower-limit value storage unit 1592 itself to the maximum value selection unit 1591. The maximum value selection unit 1591 compares the suppression coefficient by the integrated frequency band being inputted from the noise suppression coefficient calculation unit 630 of FIG. 13 or the product calculated in the multiplier 1597 with the lower limit value of the suppression coefficient being inputted from the suppression coefficient lower-limit value storage unit 1592, and outputs the value, which is larger, as a amended suppression coefficient C_{L}(m). That is, the suppression coefficient becomes a value that is equal to or more than the lower limit value stored by the suppression coefficient lower-limit value storage unit 1592 without fail. At this time, the amended suppression coefficient, being an output of the maximum value selection unit 1591, becomes noise suppression information. When the suppression coefficient is not amended, C_{L}(m)=C_{L}(m)-bar is yielded.

So far, the calculation of the noise suppression information in which the shift register 440 for outputting the value indicative of the status of the past processing frame, the estimated noise storage unit 3201, the acquired SNR storage unit 6202, and so on were involved was explained with the case exemplified of outputting the value of the past processing frame that was indicated by an index number identical to that of the integrated frequency band of the current processing frame. However, when the integrated frequency band differ processing frame by processing frame, the actual frequency band differs in some cases even though the index number of the integrated frequency band in the current processing frame is identical to that of the integrated frequency band in the past processing frame. In this case, making a configuration so that the value indicated by the index number of a band nearest to the above band, out of the stored values of the past processing frames, is outputted enables the high-quality noise suppression to be realized in the current processing frame. Further, the value equivalent to the above band of the current processing frame can be also calculated to employ this without using the stored value of the past processing frame as it stands.

Above, the explanation of the first configuration of the noise suppression information calculation unit 9 is finished.

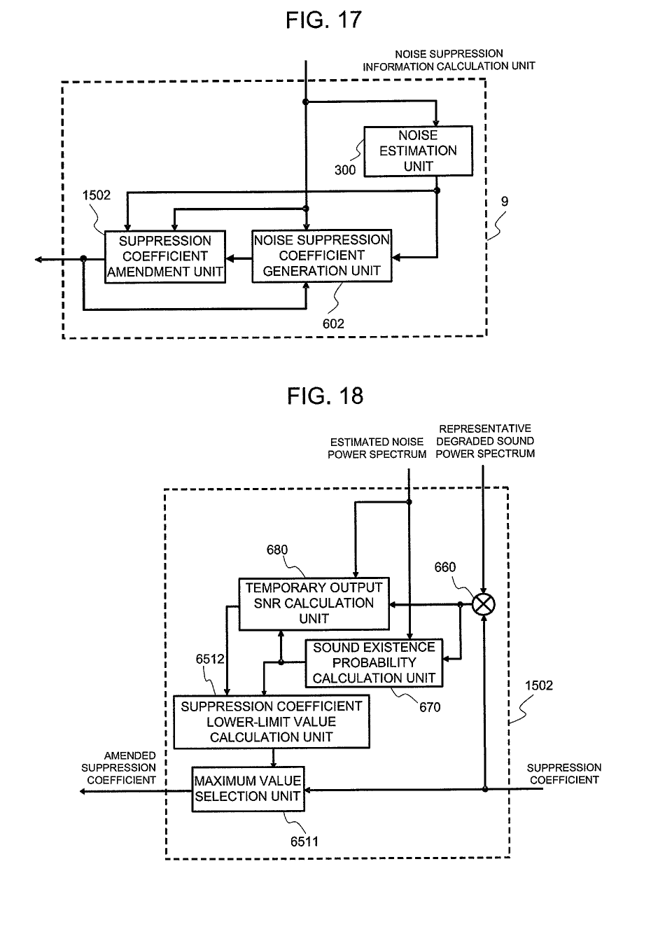

Continuously, a second configuration example of the noise suppression information calculation unit 9 of FIG. 1 will be explained in details by making a reference to FIG. 17. Upon making a comparison with the noise suppression information calculation unit 9 of FIG. 7, this noise suppression information calculation unit 9 differs in a point that the noise suppression coefficient generation unit 601 is replaced with a noise suppression coefficient generation unit 602, and the suppression coefficient amendment unit 1501 is replaced with a suppression coefficient amendment unit 1502. The noise suppression coefficient generation unit 602, upon making a comparison with the noise suppression coefficient generation unit 601 shown in FIG. 13, differs in a point of not outputting the estimated inherent SNR, being an output of the estimated inherent-SNR calculation unit 620, and is identical in an operation of the remaining part.

A configuration of the suppression coefficient amendment unit 1502 being included in FIG. 17 will be explained in details by making a reference to FIG. 18. The suppression coefficient amendment unit 1502 is configured of a multiplier 660, a sound existence probability calculation unit 670, a temporary output SNR calculation unit 680, a suppression coefficient lower-limit value calculation unit 6512, and a maximum value selection unit 6511.

The multiplier 660 obtains a product of the representative degraded sound power spectrum and the suppression coefficient, and outputs it as a temporary emphasized sound power spectrum to the sound existence probability calculation unit 670 and the temporary output SNR calculation unit 680. The sound existence probability calculation unit 670 obtains a sound existence probability V_{L} of the L-th processing frame from the temporary emphasized sound power spectrum and the estimated noise power spectrum, and outputs it to the temporary output SNR calculation unit 680 and the suppression coefficient lower-limit value calculation unit 6512. As one example of the sound existence probability, a ratio of the temporary emphasized sound power spectrum and the estimated noise power spectrum can be employed. The sound existence probability is high when this ratio is large, and the sound existence probability is low when this ratio is small. The temporary output SNR calculation unit 680 obtains a temporary output SNR D_{L}(m) from the temporary output and the estimated noise power spectrum by employing the sound existence probability V_{L}, and outputs it to the suppression coefficient lower-limit value calculation unit 6512. As one example of the temporary output SNR, a long-time output SNR, which is derived from a long-time average of the temporary output, and the estimated noise power spectrum, can be employed. The temporary output SNR calculation unit 680 updates the long-time average of the temporary output responding to magnitude of the sound existence probability V_{L} inputted from the sound existence probability calculation unit 670.

The suppression coefficient lower-limit value calculation unit 6512 calculates the lower-limit value of the suppression coefficient from the temporary output SNR D_{L}(m) and the sound existence probability V_{L}, and outputs it to the maximum value selection unit 6511. A lower-limit value A(V_{L},D_{L}(m)) of the suppression coefficient can be expressed based upon the following equation by employing a function A(D_{L}(m)) and a suppression coefficient minimum-value fₛ corresponding to a sound section.

A(V_{L},D_{L}(m))=fₛ·V_{L}+(1−V_{L})·A(D_{L}(m)) [Numerical equation 14]

The function A(D_{L}(m)), basically, has a shape such that for a large SNR, a small value is yielded. The fact that A(D_{L}(m)) is a function assuming such a shape responding to the temporary output SNR D_{L}(m) means that the higher the temporary output SNR is, the smaller the lower-limit value of the suppression coefficient corresponding to a non-sound section becomes. This, which corresponds to a decrease in residual noise, has an effect of reducing a discontinuity of the sound quality between the sound section and the non-sound section. Additionally, The function A(D_{L}(m)) may differ for each of all frequency components, and the common function A(D_{L}(m)) may be employed for a plurality of the frequency components. Further, it is also possible that the shape changes with a lapse of the time.

The maximum value selection unit 6511 compares the suppression coefficient C_{L}(m)-bar inputted from the noise suppression coefficient calculation unit 630 with the lower-limit value of the suppression coefficient inputted from the suppression coefficient lower-limit value calculation unit 6512, and outputs the larger value as the amended suppression coefficient C_{L}(m). This process can be expressed with the following equation.

$${C}_{L} ( m ) = \{ \begin{matrix}{\overline{C}}_{L} ( m ) & {\overline{C}}_{L} ( m ) \geq A ( {V}_{L ,} {D}_{L} ( m ) ) \\ A ( {V}_{L} , {D}_{L} ( m ) ) & {\overline{C}}_{L} ( m ) < A ( {V}_{L} , {D}_{L} ( m ) )\end{matrix} \qquad [ Numerical equation 15 ]$$

That is, fₛ becomes a suppression coefficient minimum value when the section is completely considered as a sound section, and the value, which is decided responding to the temporary output D_{L}(m) with a monotone decrease function, becomes a suppression coefficient minimum value when the section is completely considered as a non-sound section. In a situation where the section is considered to be an in-between section of both, these values are adequately mixed. Owing to the monotone decrease of A(D_{L}(m)), the large suppression coefficient minimum value at the time of the low SNR is guaranteed. With this, the continuity from the just-before sound section in which a lot of the not-deleted noise still survives is maintained. The control is taken in the high SNR so that the suppression coefficient minimum value is made small, and the residual noise is made small. The reason is that the continuity is maintained also when the residual noise of the non-sound section is small because the residual noise of the sound section is negligibly small. Further, setting fₛ so that it is larger than A(D_{L}(m)) allows a level of the noise suppression to be alleviated in the case of the sound section, or in the case that a possibility that the section is a sound section is high, thereby enabling a distortion occurring in the sound to be reduced. This is particularly effective in the case that the precision at which the noise is estimated cannot raised sufficiently in the sound in which a distortion caused by coding/decoding has been mixed.

Above, the explanation of the second configuration of the noise suppression information calculation unit 9 is finished.

Returning to FIG. 1, a configuration of the best mode of the present invention will be explained. The noise suppression processing unit 10 calculates an emphasized sound power spectrum |Xₙ(k)|²-bar by employing the degraded sound power spectrum, the processing frame information, and the noise suppression information, and outputs it to the inverse conversion unit 6. For example, applying the common noise suppression information for the degraded sound power spectrum being included the integrated frequency band m of the L-th processing frame makes it possible to calculate the emphasized sound power spectrum. That is, the degraded sound power spectrum used at the moment of calculating the representative degraded sound power spectrum Z_{L}(m) of [Numerical equation 5] is multiplied by a common noise suppression information C_{L}(m). This is equivalent to applying the common noise suppression information C_{L}(m) for all of degraded sound power spectra that are included in one grid encircled with gray in FIG. 4 and FIG. 6. The emphasized sound power spectrum |Xₙ(k)|²-bar becomes the following equation.

| X̅ₙ(k)|²=C_{L}²(m)| Y̅ₙ(k)|²(n_{L}≦n<n_{L+1},kₘ≦k<kₘ₊₁) [Numerical equation 16]

As another method of calculating the emphasized sound power spectrum, there also exists the method of calculating the emphasized sound power spectrum by employing the noise suppression information of a plurality of the processing frames. For example, upon performing an interpolation by employing noise suppression information C_{L-1}(m) of the one-before processing frame, the following equation is yielded.

$$[ Numerical equation 17 ]$$

$${\vert {\overline{X}}_{n} ( k ) \vert}^{2} = ( {C}_{L - 1}^{2} ( m ) + n \cdot \frac{{C}_{L}^{2} ( m ) - {C}_{L - 1}^{2} ( m )}{{n}_{L + 1} - {n}_{L}} ) \cdot {\vert {\overline{Y}}_{n} ( k ) \vert}^{2} ( {n}_{L} \leq n < {n}_{L + 1} , {k}_{m} \leq k < {k}_{m + 1} )$$

Employing the noise suppression information interpolated in such a manner makes it possible to reduce a feeling of discontinuousness in the adjacent of a boundary of the processing frame, and to realize the high-quality noise suppression. Further, the above-mentioned method may be employed after performing the smoothing for the noise suppression information of a plurality of the processing frames in advance. In this case, a drastic change in the noise suppression information can be avoided, and the high-quality noise suppression can be realized. Besides, the emphasized sound power spectrum may be calculated after interpolating the noise suppression information in the frequency direction in advance. Further, the noise suppression information for which the smoothing has been performed in both of the time direction and the frequency direction may be applied for the degraded sound power spectrum.

The inverse conversion unit 6 multiplies an emphasized sound amplitude spectrum |Xₙ(k)|-bar obtained by employing the emphasized sound power spectrum |Xₙ(k)|²-bar being inputted from the noise suppression processing unit 10 by the phase arg Yₙ(k) inputted from the conversion unit 5, and obtains an emphasized sound spectrum Xₙ(k)-bar. That is, the following is executed.

X̅ₙ(k)=| X̅ₙ(k)|·arg Yₙ(k) [Numerical equation 18]

The inverse conversion unit 6 subjects the obtained emphasized sound spectrum Xₙ(k)-bar to an inverse frequency conversion, and generates a time region signal. At this time, as an inverse frequency conversion that the inverse conversion unit 6 applies, the inverse conversion corresponding to the frequency conversion that the conversion unit 5 applies is preferably selected. When the conversion unit 5 performs the weighting with a window function W, it multiplies the signal subjected to the inverse frequency conversion by the window function W. When the conversion unit 5 is configured of the band-division filter bank, the inverse conversion unit 6 is configured of a band-composition filter bank. The technology relating to the band-composition filter bank and its design method is disclosed in the Non-patent document 3. The time region signal subjected to the inverse frequency conversion is outputted to the converted frame composition unit 3.

The converted frame composition unit 3 composes the inputted time region signals subjected to the inverse frequency converted, which has been divided into the converted frame lengths, and outputs the emphasized sound signal sample to the output terminal 4.

It is possible to realize the high-quality noise suppression, to reduce the number of times at which the noise suppression information is calculated, and to reduce the arithmetic quality because the noise suppression information is calculated with the processing frame having the converted frames integrated therein while the short converted frame length capable of following a change in the input signal is employed. In addition, adaptably deciding the processing frame responding to the input signal enables the high-quality noise suppression to be realized with a low arithmetic quantity.

Above, the explanation of the best mode of the present invention is finished.

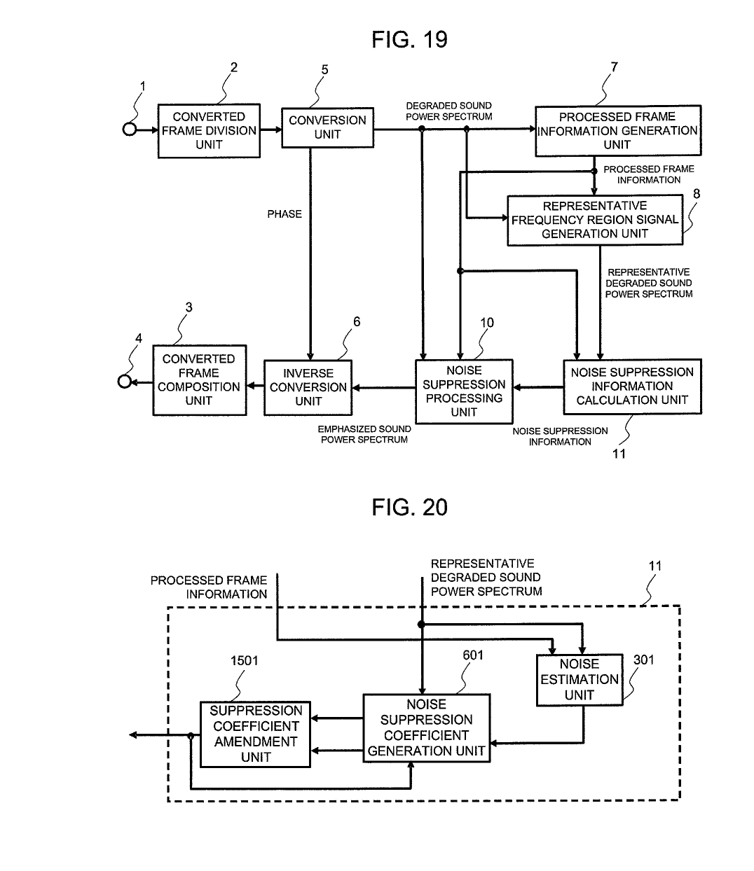

Continuously, a second embodiment of the present invention will be explained in details by making a reference to FIG. 19.

The second embodiment of the present invention, upon comparing FIG. 19 with FIG. 1 indicating the best mode, differs in a point that the noise suppression information calculation unit 9 is replaced with a noise suppression information calculation unit 11, and the processing frame information is newly inputted. Explanation of a component common to that of FIG. 1 is omitted. Hereinafter, the noise suppression information calculation unit 11 will be explained in details.

A first configuration example of the noise suppression information calculation unit 11 being included in FIG. 19 will be explained in details by making a reference to FIG. 20. This noise suppression information calculation unit 11, upon making a comparison with the noise suppression information calculation unit 9 of FIG. 7, differs in a point that the noise estimation unit 300 is replaced with a noise estimation unit 301, and the processing frame information is newly inputted.

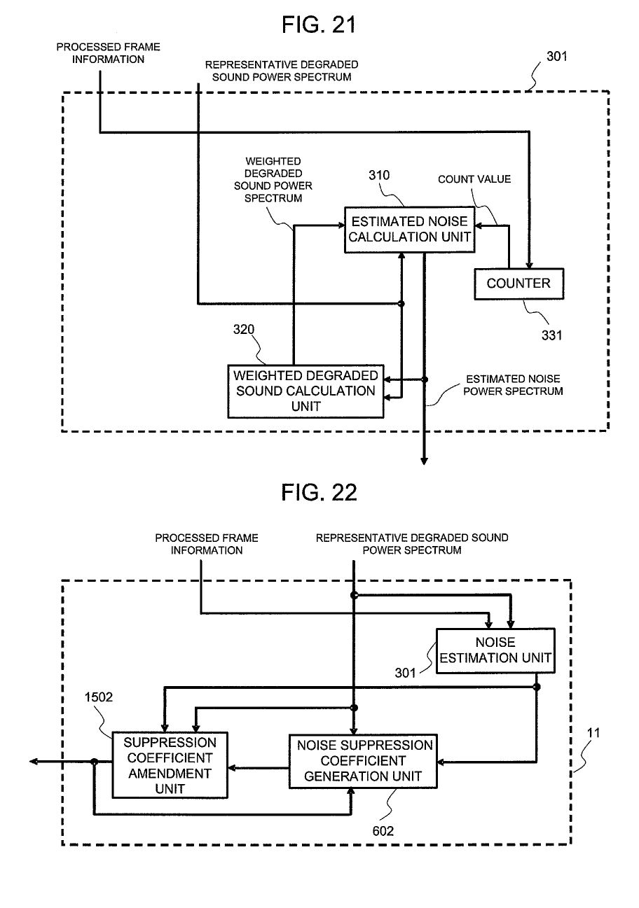

A configuration of the noise estimation unit 301 being included in FIG. 20 will be explained in details by making a reference to FIG. 21. This noise estimation unit 301 differs from the noise estimation unit 300 of FIG. 8 in a point that the counter 330 is replaced with a counter 331, and the processing frame information is newly inputted. The counter 331 outputs the count value. The initial value of the count value is set to 0. The counter 331 adds the processing frame length of the above processing frame to the count value processing frame by processing frame. That is, upon defining the count value of the L-th processing frame as Cnt(L), a count value Cnt(L+1) of the (L+1)-th processing frame becomes the following equation.

Cnt(L+1)=Cnt(L)+(n_{L+1}−n_{L}) [Numerical equation 19]

Thus, as a rule, when the update determination unit 400 of the estimated noise calculation unit 310 compares the count value of the counter 331 with the threshold, the value of the threshold storage unit 4003 of FIG. 10 is set to the value larger than the threshold that is used in the case of employing the counter 330.

With the foregoing configuration, the decided time can be accurately determined, and the noise estimation having a high standard of quality can be realized even though the processing frame length differs processing frame by processing frame.

A second configuration example of the noise suppression information calculation unit 11 will be explained in details by making a reference to FIG. 22. This noise suppression information calculation unit 11, upon making a comparison with the noise suppression information calculation unit 11 of FIG. 20, differs in a point that the noise suppression coefficient generation unit 601 is replaced with a noise suppression coefficient generation unit 602, and the suppression coefficient amendment unit 1501 is replaced with a suppression coefficient amendment unit 1502. The configuration of the noise suppression coefficient generation unit 602, and the configuration of the suppression coefficient amendment unit 1502 were already explained in details by making a reference to FIG. 17, so its explanation is omitted herein. Further, the configuration of the noise estimation unit 301 was already explained by making a reference to FIG. 21, so its explanation is omitted herein.

While the operation of the counter 331 was explained as an example of taking a control by employing the processing frame length in this embodiment, the operation is applicable the other parts as well. For example, it is also possible to employ only the weighted degraded sound power spectrum of the processing frame being included in the past time decided by the above processing frame, out of the weighted degraded power spectra saved in the shift register 440 of the estimated noise calculation unit 310, at the time of calculating the estimated noise power spectrum, and to define an average of these as an estimated noise power spectrum. With such a configuration, the estimated noise can be calculated by employing the signal within a constant time irrespectively of size of the processing frame length, whereby the noise estimation having a high standard of quality can be realized.

Above, the explanation of the second embodiment of the present invention is finished.

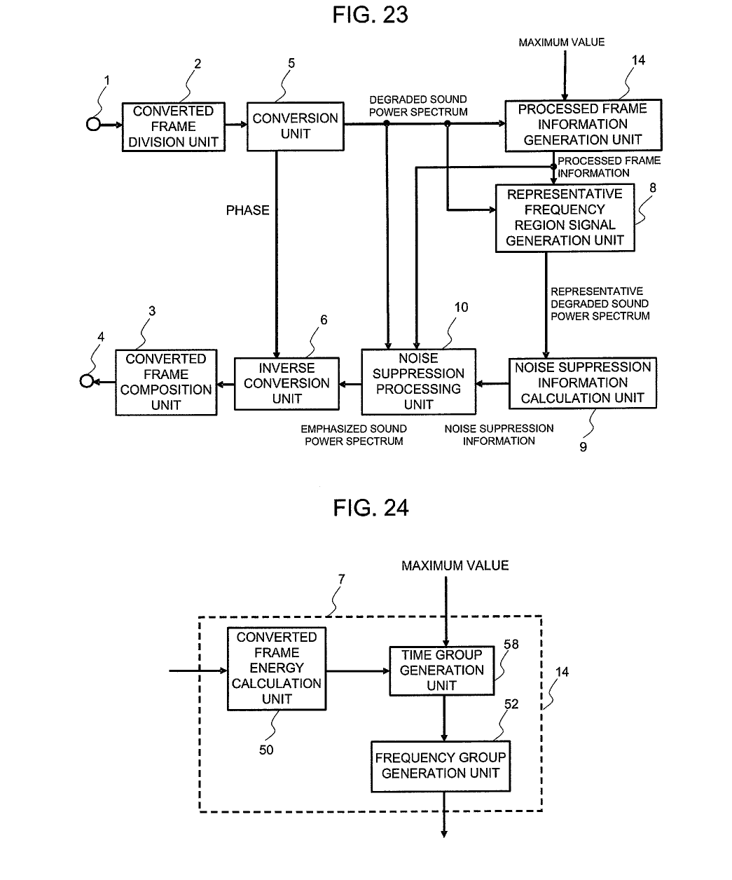

Continuously, a third embodiment of the present invention will be explained in details by making a reference to FIG. 23.

The third embodiment of the present invention, upon comparing FIG. 23 with FIG. 1 indicating the best mode, differs in a point that the processing frame information generation unit 7 is replaced with a processing frame information generation unit 14. Further, it differs in a point that the maximum value of the number of the processing frames within a decided constant time is inputted into the processing frame information generation unit 14. The processing frame information generation unit 14 decides the processing frame so that the number of the processing frames within a decided constant time is equal to or less than the inputted maximum value, and outputs the processing frame information.

A first configuration example of the processing frame information generation unit 14 of FIG. 23 will be explained in details by making a reference to FIG. 24. This processing frame information generation unit 14, upon making a comparison with the processing frame information generation unit 7 of FIG. 2, differs in a point that the time group generation unit 51 is replaced with a time group generation unit 58. Further, it differs in a point that the maximum value is inputted into the time group generation unit 58. The processing frame information generation unit 14 integrates the converted frames and decides the delimiter position of the processing frame so that, upon defining the inputted maximum number as LN, the number of the processing frames, which the time group generation unit 58 generates, within a decided constant time is equal to or less than the maximum value LN. As a method of deciding the delimiter position of the processing frame by the time group generation unit 58, there exists the method of deciding the delimiter position of the processing frame based upon a change quantity of the converted frame energy E(n) explained by employing FIG. 3. At this time, the time group generation unit 58 generates the delimiter position of the processing frame so that the processing frame is divided in the descending order of the change quality, to begin with the location in which a change quality is large. And, the time group generation unit 58 finishes the generation of the delimiter position at the time point that the number of the generated processing frames has become LN.

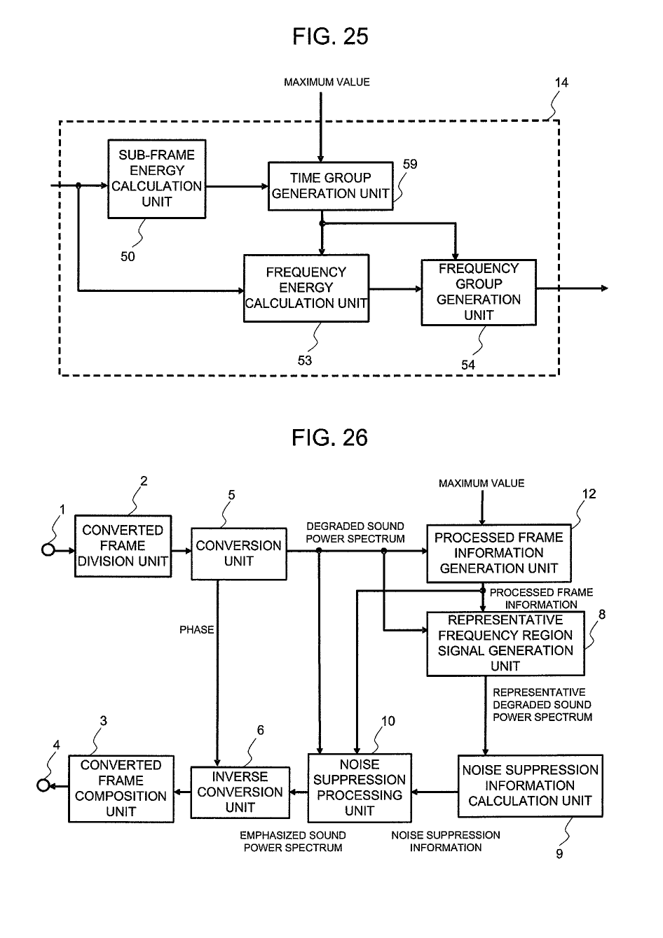

A second configuration example of the processing frame information generation unit 14 of FIG. 23 will be explained in details by making a reference to FIG. 25.

This processing frame information generation unit 14, upon making a comparison with the processing frame information generation unit 7 of FIG. 24, differs in a point of newly including a frequency energy calculation init 53, and a point that that the frequency group generation unit 52 is replaced with a frequency group generation unit 54. The frequency energy calculation unit 53 and the frequency group generation unit 54 were already explained by making a reference to FIG. 5, so its explanation is omitted herein.

Constituting the processing frame information generation unit 14 in such a manner makes it possible to decide the maximum value of the number of the processing frames within a constant time. Thus, the number of times at which the noise suppression information is calculated can be controlled and the arithmetic quantity can be reduced.

Above, the explanation of the third embodiment of the present invention is finished.

Continuously, a fourth embodiment of the present invention will be explained in details by making a reference to FIG. 26.

The fourth embodiment of the present invention, upon comparing FIG. 26 with FIG. 1 indicating the best mode, differs in a point that the processing frame information generation unit 7 is replaced with a processing frame information generation unit 12. Further, it differs only in a point that the maximum value of the number of times at which the noise suppression information is calculated in a decided constant time is newly inputted into the processing frame information generation unit 12. The processing frame information generation unit 12 decides the processing frame and the integrated frequency band so that the number of times at which the noise suppression information is calculated is equal to or less than the supplied maximum value, and outputs the processing frame information.

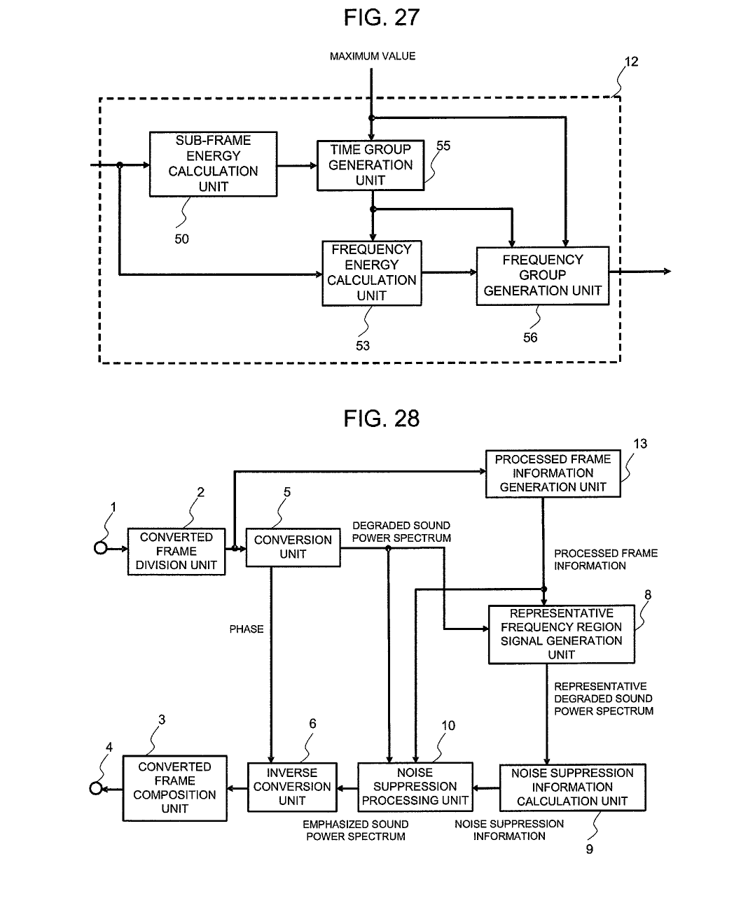

A configuration example of the processing frame information generation unit 12 of FIG. 26 will be explained in details by making a reference to FIG. 27. This processing frame information generation unit 12, upon making a comparison with the processing frame information generation unit 7 of FIG. 5, differs in a point that the time group generation unit 51 is replaced with a time group generation unit 55, and the frequency group generation unit 54 is replaced with a frequency group generation unit 56. In addition, it differs in a point that the maximum value is inputted into the time group generation unit 55 and the frequency group generation unit 56.

Upon defining the maximum value inputted into the processing frame information generation unit 12 as LM, a number TN of the processing frames that the time group generation unit 55 generates is expressed as TN=f(LM) by employing a function f. Herein, as an example of the function f, the maximum value may be defined as a positive maximum integer that does not exceed a square root of LM. Besides, the maximum value may be defined as a maximum integer that does not exceed the value obtained by dividing the maximum value LM by a constant. The time group generation unit 55 integrates the converted frames, and decides the delimiter position of the processing frame so that the number of the processing frames is TN. As a method of deciding the delimiter position of the processing frame, there exists the method of deciding the delimiter position of the processing frame based upon a change quantity of the converted frame energy E(n) as already explained by making a reference to FIG. 5. At this time, the time group generation unit 55 generates the processing frame so that the processing frame is divided in the descending order of the change quality, to begin with the location in which a change quality is large. And, the time group generation unit 55 finishes the generation of the delimiter position at the time point that the number of the generated processing frames has become TN.

The frequency group generation unit 56 integrates a plurality of the frequency bands in each processing frame, decides the delimiter position of the integrated frequency band, and outputs the processing frame information. A maximum number FN of the integrated frequency bands in each processing frame is decided as FN=int(LM/TN). Where, int(X) is a maximum integer that does not exceed X. That is, the frequency group generation unit 56 sets the integrated frequency band so that a number M_{L}, of the integrated frequency bands of the L-th processing frame already explained by making a reference to FIG. 6 does not exceed FN. At the moment of setting the integrated frequency band, the frequency group generation unit 56 decides the delimiter position so that the integrated frequency band is divided at the location in which a change in the frequency energy inputted from the frequency energy calculation unit 53 is large.

Constituting the processing frame information generation unit in such a manner makes it possible to decide the maximum value of the number of the times at which the noise suppression information is calculated within a constant time, whereby the arithmetic quantity can be reduced.

Above, the explanation of the fourth embodiment of the present invention is finished.

Continuously, a fifth embodiment of the present invention will be explained in details by making a reference to FIG. 28. The fifth embodiment of the present invention, upon comparing FIG. 28 with FIG. 1 indicating the best mode, differs in a point that the processing frame information generation unit 7 is replaced with a processing frame information generation unit 13. Further, it differs in a point that the degraded sound signal divided into the converted frames is inputted into the processing frame information generation unit 13.

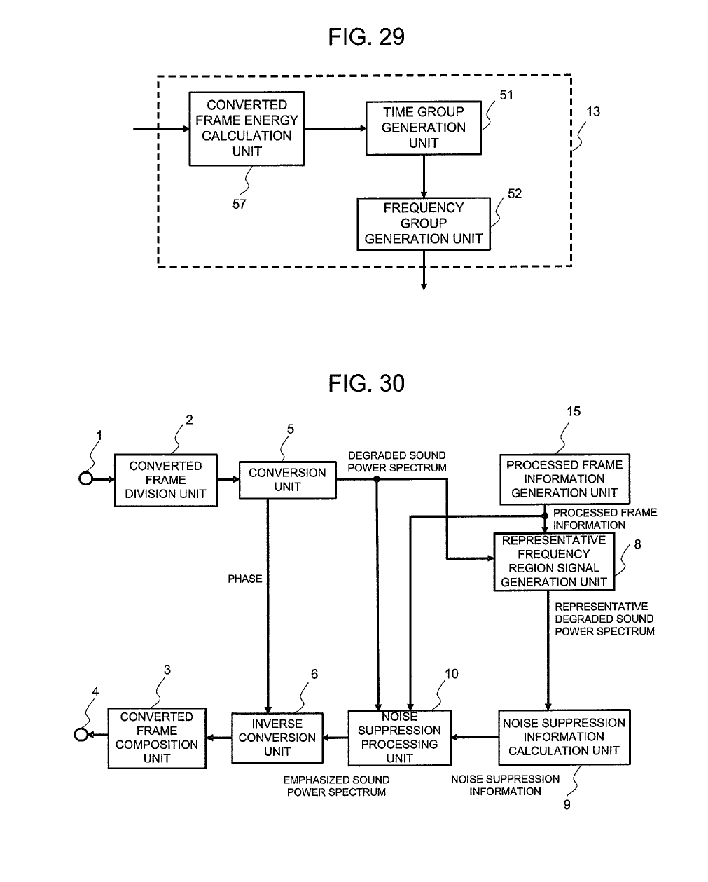

A configuration example of the processing frame information generation unit 13 will be explained in details by making a reference to FIG. 29. This processing frame information generation unit 13, upon making a comparison with the processing frame information generation unit 7 of FIG. 2, differs in a point that the converted frame energy calculation unit 50 is replaced with a converted frame energy calculation unit 57. The converted frame energy calculation unit 57 outputs a square sum of the input signal sample divided into the converted frame lengths as the converted frame energy E(n) to the time group generation unit 51.

This embodiment is characterized in that the processing frame information is calculated not by analyzing the frequency-converted signal, but by analyzing the time signal. For this reason, the frequency conversion and the calculation of the processing frame information can be performed in parallel. With this, the arithmetic quantity can be reduced. In addition, employing a parallel processor etc. enables the reduction of the arithmetic quantity to be realized all the more.

Above, the explanation of the fifth embodiment of the present invention is finished.

Continuously, a sixth embodiment of the present invention will be explained in details by making a reference to FIG. 30.

The sixth embodiment of the present invention, upon comparing FIG. 30 with FIG. 1 indicating the best mode, differs in a point that the processing frame information generation unit 7 is replaced with a processing frame information generation unit 15. The processing frame information generation unit 15 generates the processing frame information, and outputs it to the representative frequency region signal generation unit 8 and the noise suppression processing unit 10.

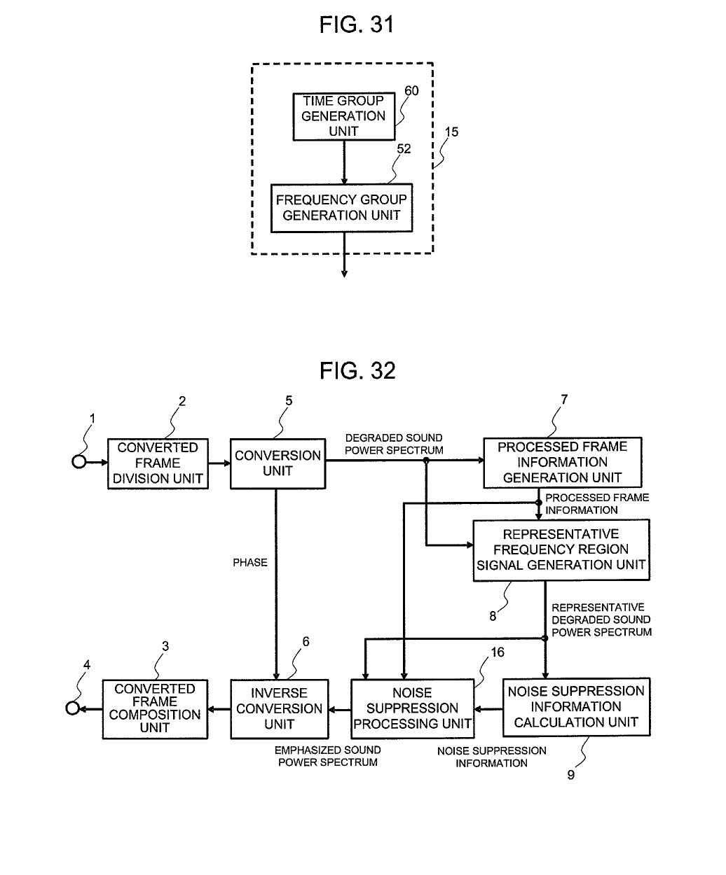

A configuration example of the processing frame information generation unit 15 will be explained in details by making a reference to FIG. 31. The processing frame information generation unit 15 is configured of a time group generation unit 60 and a frequency group generation unit 52. The time group generation unit 60 decides the delimiter position of the processing frame for calculating the representative degraded sound power spectrum, and outputs it to the frequency group generation unit 52. The time group generation unit 60 decides the delimiter position of the processing frame so that a pre-decided processing frame length is yielded. As a method of deciding the processing frame length, there exists the method of deciding the processing frame length responding to a sampling frequency of the input signal, or an arithmetic ability. For example, the delimiter position of the processing frame is decided so that the processing frame length becomes longer as the sampling frequency becomes higher. With this, the time of one processing frame in the case of the high sampling frequency can be equalized to that of one processing frame in the case of the low sampling frequency. Further, deciding the delimiter position so that the processing frame length becomes long when the arithmetic ability is low makes it possible to reduce the number of times of the calculation of the noise suppression information, which is performed thereafter. Further, the delimiter position of the processing frame may be decided based upon the resources, which the noise suppressor can use, with allocation of the resources to the other functions taken into consideration. In this case, the processing frame length is decided responding to the resources that the noise suppressor can use because the resources that the noise suppressor can use varies every moment. The operation of the frequency group generation unit 52 was already explained in details by making a reference to FIG. 2, so its explanation is omitted herein. Herein, the delimiter position of the integrated frequency band can be also decided based upon the arithmetic ability or the allocation of the resources to the other functions.

Constituting the processing frame information generation unit 15 in such a manner makes it possible to drastically reduce the arithmetic quantity for calculating the processing frame information, whereby the noise suppression is performed with a low arithmetic quantity.

Above, the explanation of the sixth embodiment of the present invention is finished.

Continuously, a seventh embodiment of the present invention will be explained in details by making a reference to FIG. 32.

The seventh embodiment of the present invention, upon comparing FIG. 32 with FIG. 1 indicating the best mode, differs in a point that the noise suppression processing unit 10 is replaced with a noise suppression processing unit 16. In addition, it differs in a point that not the degraded sound power spectrum, but the representative degraded sound power spectrum is inputted into the noise suppression processing unit 16.

The noise suppression processing unit 16 calculates the emphasized sound power spectrum from the noise suppression information C_{L}(m), the processing frame information, and the representative degraded sound power spectrum, and outputs it to the inverse conversion unit 6. The emphasized sound power spectrum |Xₙ(k)|²-bar becomes the following equation.

| X̅ₙ(k)|²=C_{L}²(m)·Z_{L}(m)(n_{L}≦n<n_{L+1},kₘ≦k<kₘ₊₁) [Numerical equation 20]

As another method of calculating the emphasized sound power spectrum, there also exists the method of calculating the emphasized sound power spectrum by employing the noise suppression information of a plurality of the processing frames. For example, upon performing an interpolation by employing noise suppression information C_{L-1}(m) of the one-before processing frame, the following equation is yielded.

$$[ Numerical equation 21 ]$$

$${\vert {\overline{X}}_{n} ( k ) \vert}^{2} = ( {C}_{L - 1}^{2} ( m ) + n \cdot \frac{{C}_{L}^{2} ( m ) - {C}_{L - 1}^{2} ( m )}{{n}_{L + 1} - {n}_{L}} ) \cdot {Z}_{L} ( m ) ( {n}_{L} \leq n < {n}_{L + 1} , {k}_{m} \leq k < {k}_{m + 1} )$$

Needless to say, the interpolation may be performed from the noise suppression information of a plurality of the processing frames. Employing the noise suppression information interpolated in such a manner makes it possible to reduce a feeling of discontinuousness in the adjacent of a boundary of the processing frame, and to realize the high-quality noise suppression. Further, the above-mentioned method may be employed after performing the smoothing for the noise suppression information of a plurality of the processing frames in advance. In this case, a drastic change in the noise suppression information can be avoided, and the high-quality noise suppression can be realized. Besides, the emphasized sound power spectrum may be calculated after interpolating the noise suppression information in the frequency direction in advance. Further, the noise suppression information for which the smoothing has been performed in both of the time direction and the frequency direction may be applied for the degraded sound power spectrum.

Above, the explanation of the seventh embodiment of the present invention is finished.

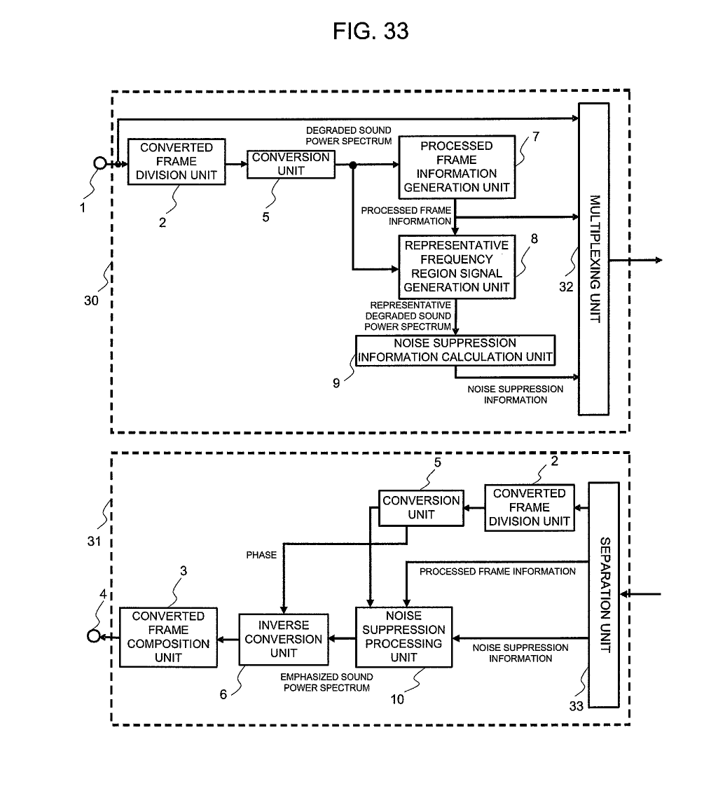

Continuously, an eighth embodiment of the present invention will be explained in details by making a reference to FIG. 33.

The eighth embodiment of the present invention is configured of a record unit 30 and a reproduction unit 31. The record unit 30, into which the input signal is inputted from the input terminal 1, calculates information for suppressing the noise of the input signal, multiplexes the input signal and the calculated information, and outputs a multiplexed signal. On the other hand, the reproduction unit 31 receives the multiplexed signal outputted by the record unit 30, suppresses the noise of the input signal being included in the multiplexed signal based upon the information for suppressing the noise being included in the multiplexed signal, and outputs it to the output terminal 4.

The record unit 30 is configured of the converted frame division unit 2, the conversion unit 5, the processing frame information generation unit 7, the representative frequency region signal generation unit 8, the noise suppression information calculation unit 9, and a multiplexing unit 32. The converted frame division unit 2, the conversion unit 5, the processing frame information generation unit 7, the representative frequency region signal generation unit 8, and the noise suppression information calculation unit 9 were already explained by making a reference to FIG. 1, so its explanation is omitted herein.

The multiplexing unit 32 multiplexes the input signal and the processing frame information, and outputs the multiplexed signal.

The reproduction unit 31 is configured of a separation unit 33, the converted frame division unit 2, the conversion unit 5, the noise suppression processing unit 10, the inverse conversion unit 6, and the converted frame composition unit 3. The converted frame division unit 2, the conversion unit 5, the noise suppression processing unit 10, the inverse conversion unit 6, and the converted frame composition unit 3 were already explained by making a reference to FIG. 1, so its explanation is omitted herein.

The separation unit 33 separates the inputted multiplexed signal into the input signal, the processing frame information, and the noise suppression information, outputs the input signal to the converted frame division unit 2, and outputs the processing frame information and the noise suppression information to the noise suppression processing unit 10.

Herein, the multiplexed signal may be saved in an accumulation medium temporarily so as to take out the multiplexed signal from the accumulation medium at the time of reproduction. Further, it is not that the input signal is multiplexed as it stands, but that the input signal may be encoded to multiplex the information-compressed data. In this case, the reproduction unit 31 is provided with a decoding unit, being a function of decoding the input signal that is opposite to that of the record unit 30. Likewise, it is apparent that the processing frame information and the noise suppression information can be encoded.

While, herein, the explanation was made on the assumption that the record unit 30 and the reproduction unit 31 existed in an identical terminal, each of the record unit 30 and the reproduction unit 31 may exist in a different terminal. In this case, the multiplexed signal, being an output of the record unit 30, may be outputted to the reproduction unit 31 existing in another terminal through a transmission path etc. Further, the multiplexed signal may be preserved in the accumulation medium to input it into the reproduction unit 31 existing in another terminal.

Making a configuration in such a manner makes it possible to reduce the arithmetic quantity because the noise suppression information does not need to be calculated at the moment of reproducing the recorded signal.

Above, the explanation of the eighth embodiment of the present invention is finished.

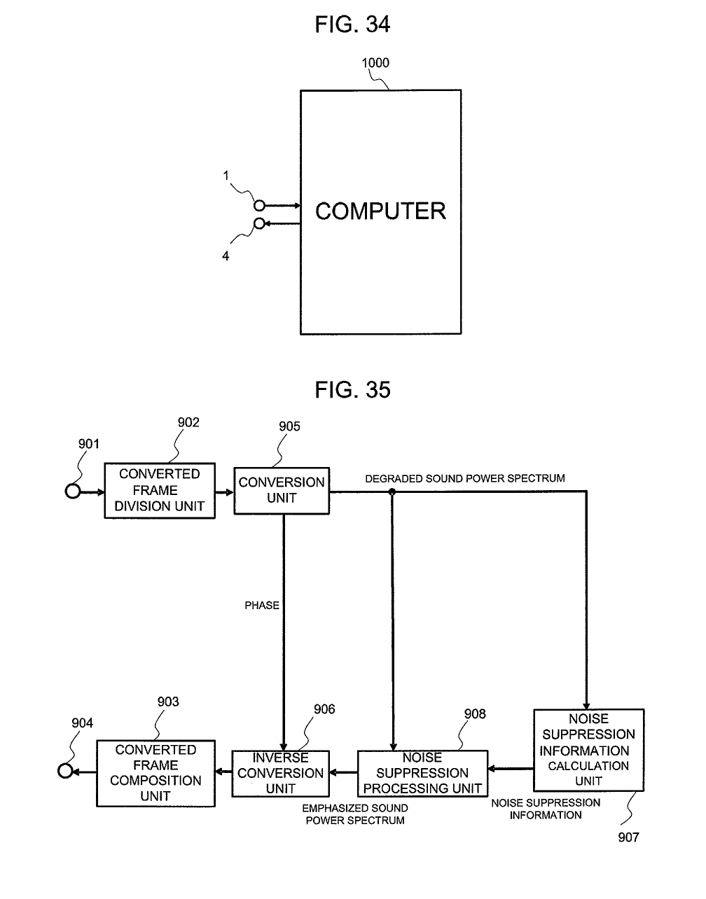

Continuously, a ninth embodiment of the present invention will be explained in details by making a reference to FIG. 34.

The ninth embodiment of the present invention is provided with a computer 1000 that operates under a program control. The computer 1000, which performs the process relating to any of the foregoing best mode and second embodiment to eighth embodiment of the present invention for the input signal received from the input terminal 1, operates based upon a program for outputting the emphasized sound to the output terminal 4.

Above, the explanation of the ninth embodiment of the present invention is finished.

While all of the embodiments were explained so far on the assumption that the minimum mean-square error short-time spectral amplitude technique was employed as a technique of suppressing the noise, the other methods as well are applicable. As an example of such a method, there exist the Wiener filtering method disclosed in Non-patent document 5 (PROCEEDINGS OF THE IEEE, Vol. 67. No. 12, pp. 1586 to 1604, December, 1979) and the spectrum subtraction method disclosed in Non-patent document 6 (IEEE TRANSACTIONS ON ACOUSTICS, SPEECH, AND SIGNAL PROCESSING, Vol. 27. No. 2, pp. 113 to 120, April, 1979), and explanation of these detailed configuration examples is omitted.

While the embodiments were explained above, examples of the present invention will be described below.

The 1st embodiment of the present invention is characterized in that a noise suppression device, comprising: a conversion means for converting an input signal into a frequency region signal for each decided first frame; a frame generation means for generating a second frame so that it differs from said first frame; a representative frequency region signal generation means for generating a representative frequency region signal from said frequency region signal of the first frame being included in said second frame; and a noise suppression degree calculation means for obtaining a degree of noise suppression of said second frame based upon said representative frequency region signal.

Furthermore, the 2nd embodiment of the present invention is characterized in that, in the above-mentioned embodiment, said frame generation means generates the second frame of which a frame length is longer than that of said first frame.

Furthermore, the 3rd embodiment of the present invention is characterized in that, in the above-mentioned embodiments, said frame generation means generates said second frame so that said second frame partners are made independent of each other.

Furthermore, the 4th embodiment of the present invention is characterized in that, in the above-mentioned embodiments, said noise suppression degree calculation means applies said degree of the noise suppression for said frequency region signal being included in said second frame, thereby to suppress noise.

Furthermore, the 5th embodiment of the present invention is characterized in that, in the above-mentioned embodiments, said noise suppression degree calculation means applies a degree of the noise suppression calculated by interpolating said degree of the noise suppression of the other second frames for said frequency region signal being included in said second frame, thereby to suppress noise.

Furthermore, the 6th embodiment of the present invention is characterized in that, in the above-mentioned embodiments, said frame generation means generates the second frame based upon a feature of said frequency region signal.

Furthermore, the 7th embodiment of the present invention is characterized in that, in the above-mentioned embodiments, said feature of the frequency region signal is a change in an energy of said input signal.

Furthermore, the 8th embodiment of the present invention is characterized in that, in the above-mentioned embodiments, the noise suppression device comprising a frequency delimiter position generation means for generating a delimiter position in a frequency direction for each said second frame, and said representative frequency region signal generation means generates said representative frequency region signal from said frequency region signal based upon said second frame and said delimiter position in the frequency direction.

Furthermore, the 9th embodiment of the present invention is characterized in that, in the above-mentioned embodiments, said frame generation means generates said second frame so that the number of the second frames in a constant block is within a range of a pre-decided number.

Furthermore, the 10th embodiment of the present invention is characterized in that, in the above-mentioned embodiments, said frame generation means obtains said second frame and said delimiter position in the frequency direction so that the number of times at which said degree of the noise suppression is calculated in a constant block is within a range of a pre-decided number of times.

Furthermore, the 11th embodiment of the present invention is characterized in that, in of the above-mentioned embodiments, said degree of the noise suppression is expressed as a noise suppression coefficient.

Furthermore, the 12th embodiment of the present invention is characterized in that, in the above-mentioned embodiments, said degree of the noise suppression is expressed as an estimated value of the noise.

The 13th embodiment of the present invention is characterized in that a noise suppression method comprising: a conversion step of converting an input signal into a frequency region signal for each decided first frame; a frame generation step of generating a second frame so that it differs from said first frame; a representative frequency region signal generation step of generating a representative frequency region signal from said frequency region signal of the first frame being included in said second frame; and a noise suppression degree calculation step of obtaining a degree of noise suppression of said second frame based upon said representative frequency region signal.

Furthermore, the 14th embodiment of the present invention is characterized in that, in the above-mentioned embodiments, said frame generation step generates said second frame of which a frame length is longer than that of said first frame.

Furthermore, the 15th embodiment of the present invention is characterized in that, in the above-mentioned embodiments, said frame generation step generates said second frame so that said second frame partners are made independent of each other.

Furthermore, the 16th embodiment of the present invention is characterized in that, in the above-mentioned embodiments, said noise suppression degree calculation steps applies said degree of the noise suppression for said frequency region signal being included in said second frame, thereby to suppress noise.

Furthermore, the 17th embodiment of the present invention is characterized in that, in the above-mentioned embodiments, said noise suppression degree calculation steps applies a degree of the noise suppression calculated by interpolating said degree of the noise suppression of the other second frames for said frequency region signal being included in said second frame, thereby to suppress noise.

Furthermore, the 18th embodiment of the present invention is characterized in that, in the above-mentioned embodiments, said frame generation step generates said second frame based upon a feature of said frequency region signal.

Furthermore, the 19th embodiment of the present invention is characterized in that, in the above-mentioned embodiments, said feature of the frequency region signal is a change in an energy of said input signal.

Furthermore, the 20th embodiment of the present invention is characterized in that, in the above-mentioned embodiments, the a noise suppression method comprising a frequency delimiter position generation step of generating a delimiter position in a frequency direction for each said second frame, and said representative frequency region signal generation step generates the representative frequency region signal from said frequency region signal based upon said second frame and said delimiter position in the frequency direction.

Furthermore, the 21st embodiment of the present invention is characterized in that, in the above-mentioned embodiments, said frame generation step generates said second frame so that the number of said second frames in a constant block is within a range of a pre-decided number.

Furthermore, the 22nd embodiment of the present invention is characterized in that, in the above-mentioned embodiments, said frame generation step generates said second frame and said delimiter position in the frequency direction so that the number of times at which said degree of the noise suppression is calculated in a constant block is within a range of a pre-decided number of times.

Furthermore, the 23rd embodiment of the present invention is characterized in that, in the above-mentioned embodiments, in said noise suppression degree calculation step, said degree of the noise suppression is expressed as a noise suppression coefficient.

Furthermore, the 24th embodiment of the present invention is characterized in that, in the above-mentioned embodiments, in said noise suppression degree calculation step, said degree of the noise suppression is expressed as an estimated value of the noise.

Furthermore, the 25th embodiment of the present invention is characterized in that a noise suppression program for causing a computer to execute: a conversion process of converting an input signal into a frequency region signal for each decided first frame; a frame generation process of generating a second frame so that it differs from said first frame; a representative frequency region signal generation process of generating a representative frequency region signal from said frequency region signal of the first frame being included in said second frame; and a noise suppression degree calculation process of obtaining a degree of noise suppression of said second frame based upon said representative frequency region signal.

Furthermore, the 26th embodiment of the present invention is characterized in that, in the above-mentioned embodiments, said frame generation process generates said second frame of which a frame length is longer than that of said first frame.

Furthermore, the 27th embodiment of the present invention is characterized in that, in the above-mentioned embodiments, said frame generation process generates said second frame so that said second frame partners are made independent of each other.

Furthermore, the 28th embodiment of the present invention is characterized in that, in the above-mentioned embodiments, said noise suppression degree calculation process applies said degree of the noise suppression for said frequency region signal being included in said second frame, thereby to suppress noise.

Furthermore, the 29th embodiment of the present invention is characterized in that, in the above-mentioned embodiments, said noise suppression degree calculation process applies a degree of the noise suppression calculated by interpolating said degree of the noise suppression of the other second frames for said frequency region signal being included in said second frame, thereby to suppress noise.

Furthermore, the 30th embodiment of the present invention is characterized in that, in the above-mentioned embodiments, said frame generation process generates said second frame based upon a feature of said frequency region signal.

Furthermore, the 31st embodiment of the present invention is characterized in that, in the above-mentioned embodiments, said feature of the frequency region signal is a change in an energy of said input signal.

Furthermore, the 32nd embodiment of the present invention is characterized in that, in the above-mentioned embodiments, the a noise suppression program comprising a frequency delimiter position generation process of generating a delimiter position in a frequency direction for each said second frame, and said representative frequency region signal generation process generates the representative frequency region signal from said frequency region signal based upon said second frame and said delimiter position in the frequency direction.

Furthermore, the 33rd embodiment of the present invention is characterized in that, in the above-mentioned embodiments, said frame generation process generates said second frame so that the number of said second frames in a constant block is within a range of a pre-decided number.

Furthermore, the 34th embodiment of the present invention is characterized in that, in the above-mentioned embodiments, said frame generation process generates said second frame and said delimiter position in the frequency direction so that the number of times at which said degree of the noise suppression is calculated in a constant block is within a range of a pre-decided number of times.

Furthermore, the 35th embodiment of the present invention is characterized in that, in the above-mentioned embodiments, in said noise suppression degree calculation process, said degree of the noise suppression is expressed as a noise suppression coefficient.

Furthermore, the 36th embodiment of the present invention is characterized in that, in the above-mentioned embodiments, in said noise suppression degree calculation process, said degree of the noise suppression is expressed as an estimated value of the noise.

Above, while the present invention has been described with respect to the preferred embodiments and examples, the present invention is not always limited to the above-mentioned embodiment and examples, and alterations to, variations of, and equivalent to these embodiments and the examples can be implemented without departing from the spirit and scope of the present invention.

This application is based upon and claims the benefit of priority from Japanese patent application No. 2007-243001, filed on Sep. 19, 2007, the disclosure of which is incorporated herein in its entirety by reference.

1. A noise suppression device, comprising:
a converter that converts an input signal into a frequency region signal for each decided first frame;
a frame generator that generates a second frame so that it differs from said first frame;
a representative frequency region signal generator that generates a representative frequency region signal from said frequency region signal of the first frame being included in said second frame; and
a noise suppression degree calculator that obtains a degree of noise suppression of said second frame based upon said representative frequency region signal.

2. A noise suppression device according to claim 1, wherein said frame generator generates the second frame of which a frame length is longer than that of said first frame.

3. A noise suppression device according to claim 1, wherein said frame generator generates said second frame so that said second frame partners are made independent of each other.

4. A noise suppression device according to claim 1, wherein said noise suppression degree calculator applies said degree of the noise suppression for said frequency region signal being included in said second frame, thereby to suppress noise.

5. A noise suppression device according to claim 1, wherein said noise suppression degree calculator applies a degree of the noise suppression calculated by interpolating said degree of the noise suppression of the other second frames for said frequency region signal being included in said second frame, thereby to suppress noise.

6. A noise suppression device according to claim 1, wherein said frame generator generates the second frame based upon a feature of said frequency region signal.

7. A noise suppression device according to claim 6, wherein said feature of the frequency region signal is a change in an energy of said input signal.

8. A noise suppression device according to claim 1,
comprising a frequency delimiter position generator that generates a delimiter position in a frequency direction for each said second frame,
wherein said representative frequency region signal generator generates said representative frequency region signal from said frequency region signal based upon said second frame and said delimiter position in the frequency direction.

9. A noise suppression device according to claim 1, wherein said frame generator generates said second frame so that the number of the second frames in a constant block is within a range of a pre-decided number.

10. A noise suppression device according to claim 8, wherein said frame generator obtains said second frame and said delimiter position in the frequency direction so that the number of times at which said degree of the noise suppression is calculated in a constant block is within a range of a pre-decided number of times.

11. A noise suppression device according to claim 1, wherein said degree of the noise suppression is expressed as a noise suppression coefficient.

12. A noise suppression device according to claim 1, wherein said degree of the noise suppression is expressed as an estimated value of the noise.

13. A noise suppression method, comprising:
a conversion step of converting an input signal into a frequency region signal for each decided first frame;
a frame generation step of generating a second frame so that it differs from said first frame;
a representative frequency region signal generation step of generating a representative frequency region signal from said frequency region signal of the first frame being included in said second frame; and
a noise suppression degree calculation step of obtaining a degree of noise suppression of said second frame based upon said representative frequency region signal.

14. A noise suppression method according to claim 13, wherein said frame generation step generates said second frame of which a frame length is longer than that of said first frame.

15. A noise suppression method according to claim 13, wherein said frame generation step generates said second frame so that said second frame partners are made independent of each other.

16. A noise suppression method according to claim 13, wherein said noise suppression degree calculation steps applies said degree of the noise suppression for said frequency region signal being included in said second frame, thereby to suppress noise.

17. A noise suppression method according to claim 13, wherein said noise suppression degree calculation steps applies a degree of the noise suppression calculated by interpolating said degree of the noise suppression of the other second frames for said frequency region signal being included in said second frame, thereby to suppress noise.

18. A noise suppression method according to claim 13, wherein said frame generation step generates said second frame based upon a feature of said frequency region signal.

19. A noise suppression method according to claim 18, wherein said feature of the frequency region signal is a change in an energy of said input signal.

20. (canceled)

21. (canceled)

22. (canceled)

23. (canceled)

24. (canceled)

25. A recording medium in which a noise suppression program for causing a computer to execute:
a conversion process of converting an input signal into a frequency region signal for each decided first frame;
a frame generation process of generating a second frame so that it differs from said first frame;
a representative frequency region signal generation process of generating a representative frequency region signal from said frequency region signal of the first frame being included in said second frame; and
a noise suppression degree calculation process of obtaining a degree of noise suppression of said second frame based upon said representative frequency region signal.

26. (canceled)

27. (canceled)

28. (canceled)

29. (canceled)

30. (canceled)

31. (canceled)

32. (canceled)

33. (canceled)

34. (canceled)

35. (canceled)

36. (canceled)
